(19) United States
(12) Patent Application Publication
(10) Pub. No.: US 2006/0054889 A1
(43) Pub. Date: Mar. 16, 2006

(54) Thin film transistor array panel

(76) Inventors: Jang-Soo Kim, Suwon-si (KR); Hyang-Shik Kong, Suwon-si (KR); Hye-Young Ryu, Seoul (KR); Sung-Man Kim, Seoul (KR)

Correspondence Address: McGuireWoods LLP;Suite 1800, 1750 Tysons Boulevard, McLean, VA, 22102, US

(21) Appl. No.: 10/942,039

(22) Filed: Sep. 16, 2004

(51) Int. Cl. H01L 29/04

(52) U.S. Cl. 257/59

(57) ABSTRACT

A thin film transistor array panel comprising: an insulating substrate; a plurality of gate lines formed on the insulating substrate and including a plurality of gate electrodes and end portions; a plurality of storage electrode lines formed on the insulating substrate; a gate insulating layer formed on the gate lines and storage electrode lines; a semiconductor layer formed on the gate insulating layer; a ohmic contact layer formed on the semiconductor layer; a plurality of data lines formed on the gate insulating layer, intersecting the gate lines to define a display area, and having source electrodes and end portions; a plurality of drain electrodes facing the source electrodes; a passivation layer formed on the data lines and drain electrodes and having contact holes; a plurality of pixel electrodes formed on the passivation layer and connected to the drain electrodes through the contact holes; a storage line connecting bar connecting the storage electrode lines; and a redundant connecting line connecting the storage electrode lines is provided.

### BACKGROUND OF THE INVENTION

1. Field of the Invention

The present invention relates to a thin film transistor array panel.

2. Description of the Related Art

Generally, a thin film transistor (TFT) array panel (TFT) is used as a circuit board to drive pixels independently in a liquid crystal display (LCD) or an organic electro luminescence display (OELD).

A TFT array panel includes gate lines transmitting scanning signals, data lines transmitting image signals, TFTs connected to the data lines and gate lines, pixel electrodes connected to the TFTs, a gate insulating layer covering and insulating the gate lines, and a passivation layer covering and insulating the TFTs and data lines.

A TFT include a gate electrode which is a part of the gate line, a semiconductor forming a TFT channel, a source electrode which is a part of the data line, a drain electrode, the gate insulating layer, and the passivation layer. The TFT is a switching element to regulate transmittance of the image signals to the pixel electrode according to the scanning signal.

The TFT array panel includes storage capacitance for enhancing capability of preserving a pixel voltage. The storage capacitance may be formed by using a previous gate line as a storage electrode or a separate storage electrode line.

An LCD having separate storage electrode lines includes storage line connecting bars which connect the storage electrode lines and are formed on right and left parts of a peripheral area which is outside of a display area.

In that kind of LCD, if a storage electrode line is disconnected from any of the storage line connecting bars, display defects such as a transverse stain are induced.

On a portion of the peripheral area, which includes the end side of the gate lines, since a storage line connecting bar can be formed without intersecting the gate lines, the storage line connecting bar can be formed on the same layer as the gate lines which are formed on the same layer at the storage electrode lines to allow the storage line connecting bar to directly connect to the storage electrode lines. However, on a portion of the peripheral area which includes the initiating side of the gate lines, the storage line connecting bar is obliged to intersect the gate lines. Therefore, the storage line connecting bar is formed on a different layer from the storage electrode lines. Accordingly, the storage line connecting bar and the storage electrode lines are connected by using storage contact assistants through contact holes.

In such a structure, contact portions of the storage contact assistants and the storage line connection bar or the storage electrode lines are very prone to disconnection. In particular, when the gate lines have double layers, the upper layer is undercut around the contact holes. The undercut portions are easily broken by static electricity and overflow current.

Meanwhile, the storage electrode lines can be connected to each other through ITO bridges formed in the display area. In an LCD having such a storage electrode line connection structure, the transverse stain is not induced by disconnection of the storage electrode line from the storage line connecting bars.

However, since the ITO bridges reduce the aperture ratio, the ITO bridge is not used in an LCD having a high aperture ratio.

### SUMMARY OF THE INVENTION

A thin film transistor array panel comprising: an insulating substrate; a plurality of gate lines formed on the insulating substrate and including a plurality of gate electrodes and end portions; a plurality of storage electrode lines formed on the insulating substrate; a gate insulating layer formed on the gate lines and storage electrode lines; a semiconductor layer formed on the gate insulating layer; a ohmic contact layer formed on the semiconductor layer; a plurality of data lines formed on the gate insulating layer, intersecting the gate lines to define display area, and having source electrodes and end portions; a plurality of drain electrodes facing the source electrodes; a passivation layer formed on the data lines and drain electrodes and having contact holes; a plurality of pixel electrodes formed on the passivation layer and connected to the drain electrodes through the contact holes; a storage line connecting bar connecting the storage electrode lines; and a redundant connecting line connecting the storage electrode lines is provided.

A thin film transistor array panel comprising: an insulating substrate; a plurality of gate lines formed on the insulating substrate and including a plurality of gate electrodes and end portions; a plurality of storage electrode lines formed on the insulating substrate; a gate insulating layer formed on the gate lines and storage electrode lines; a semiconductor layer formed on the gate insulating layer; a ohmic contact layer formed on the semiconductor layer; a plurality of data lines and drain electrodes formed on the ohmic contact layer and having substantially the same planar pattern as the ohmic contact layer; a passivation layer formed on the data lines and drain electrodes and having contact holes; a plurality of pixel electrodes formed on the passivation layer and connected to the drain electrodes through the contact holes; a storage line connecting bar connecting the storage electrode lines; and a redundant connecting line connecting the storage electrode lines is provided.

A thin film transistor array panel comprising: an insulating substrate; a plurality of gate lines formed on the insulating substrate and including a plurality of gate electrodes and end portions; a plurality of storage electrode lines formed on the insulating substrate; a gate insulating layer formed on the gate lines and storage electrode lines; a semiconductor layer formed on the gate insulating layer; a ohmic contact layer formed on the semiconductor layer; a plurality of data lines formed on the gate insulating layer, intersecting the gate lines to define display area, and having source electrodes and end portions; a plurality of drain electrodes facing the source electrodes; a plurality of color filters formed on the data lines and having a first contact holes exposing the drain electrodes; a passivation layer formed on the data lines and drain electrodes and having a second contact holes overlapping at least a portion of the first contact holes to expose the drain electrodes; a plurality of pixel electrodes formed on the passivation layer and connected to the drain electrodes through the second contact holes; a storage line connecting bar connecting the storage electrode lines; and a redundant connecting line connecting the storage electrode lines is provided.

A thin film transistor array panel comprising: an insulating substrate; a plurality of gate lines formed on the insulating substrate and including a plurality of gate electrodes and end portions; a plurality of storage electrode lines formed on the insulating substrate; a gate insulating layer formed on the gate lines and storage electrode lines; a semiconductor layer formed on the gate insulating layer; a ohmic contact layer formed on the semiconductor layer; a plurality of data lines and drain electrodes formed on the ohmic contact layer and having substantially the same planar pattern as the ohmic contact layer; a plurality of color filters formed on the data lines and having a first contact holes exposing the drain electrodes; a passivation layer formed on the data lines and drain electrodes and having a second contact holes overlapping at least a portion of the first contact holes to expose the drain electrodes; a plurality of pixel electrodes formed on the passivation layer and connected to the drain electrodes through the second contact holes; a storage line connecting bar connecting the storage electrode lines; and a redundant connecting line connecting the storage electrode lines is provided.

The storage line connecting bar may be formed on the gate insulating layer, and the passivation layer and gate insulating layer have third contact holes exposing the storage line connecting bar and the storage electrode lines, and storage contact assistants connecting the storage line connecting bar and the storage electrode lines through the third contact holes may be further comprised.

The passivation layer and gate insulating layer may have fourth contact holes exposing the storage electrode lines, and the redundant connecting bar may be connected to the storage electrode lines through the fourth contact holes.

The thin film transistor array panel may further comprise a repair bar formed on the gate insulating layer, disposed between the storage line connecting bar and the redundant connecting bar, and intersecting the storage electrode lines.

The repair bar and the redundant connecting bar may overlap each other.

The passivation layer and gate insulating layer may have fifth contact holes exposing the storage electrode lines, the repair bar may have penetrating holes, and the fifth contact holes may be disposed in the penetrating holes.

### BRIEF DESCRIPTION OF THE DRAWINGS

The present invention will become more apparent by describing embodiments thereof in detail with reference to the accompanying drawings, in which:

FIG. 1A is a layout view of a TFT array panel according to a first exemplary embodiment of the present invention;

FIGS. 1B and 1C are sectional views of the TFT array panel shown in FIG. 1A respectively taken along the lines IB-IB′ and IC-IC′;

FIGS. 2A to 5C are sectional views of the TFT array panel shown in FIGS. 1A-1C in intermediate steps of a manufacturing method thereof according to an embodiment of the present invention;

FIG. 6A is a layout view of a TFT array panel according to a second exemplary embodiment of the present invention;

FIGS. 6B and 6C are sectional views of the TFT array panel shown in FIG. 6C respectively taken along the lines VIB-VIB′ and VIC-VIC′;

FIG. 7A is a layout view of a TFT array panel according to a third exemplary embodiment of the present invention;

FIGS. 7B and 7D are sectional views of the TFT array panel shown in FIG. 7A respectively taken along the lines VIIB-VIIB′ and VIIC-VIIC′;

FIGS. 8A to 12D are sectional views of the TFT array panel shown in FIGS. 6A-6C in intermediate steps of a manufacturing method thereof according to an embodiment of the present invention;

FIG. 13A is a layout view of a TFT array panel according to a fourth exemplary embodiment of the present invention;

FIGS. 13B to 13D are sectional views of the TFT array panel shown in FIG. 13A respectively taken along the lines XIIIB-XIIIB′, XIIIC-XIIIC′, and XIIID-XIIID′;

FIG. 14A is a layout view of a TFT array panel according to a fifth exemplary embodiment of the present invention;

FIGS. 14B and 14D are sectional views of the TFT array panel shown in FIG. 14A respectively taken along the lines XIVB-XIVB′, XIVC-XIVC′, and XIVD-XIVD′;

FIG. 15A is a layout view of a TFT array panel according to a sixth exemplary embodiment of the present invention;

FIGS. 15B and 15E are sectional views of the TFT array panel shown in FIG. 14A respectively taken along the lines XVB-XVB′, XVC-XVC′, XVD-XVD′, and XVE-XVE′;

### DETAILED DESCRIPTION OF THE PREFERRED EMBODIMENTS

The present invention now will be described more fully hereinafter with reference to the accompanying drawings, in which preferred embodiments of the invention are shown. The present invention may, however, be embodied in many different forms and should not be construed as being limited to the embodiments set forth herein.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Now, TFT array panels and manufacturing methods thereof according to embodiments of the present invention will be described with reference to the accompanying drawings.

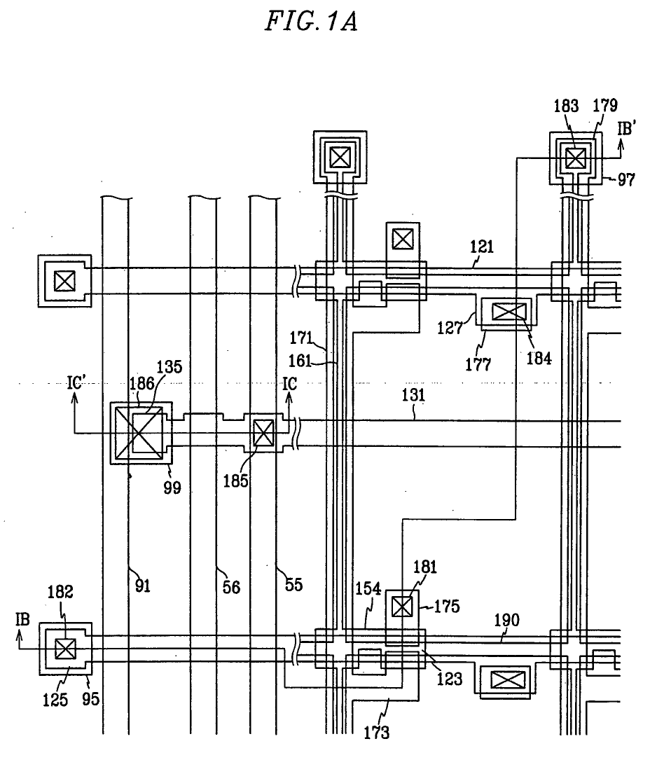

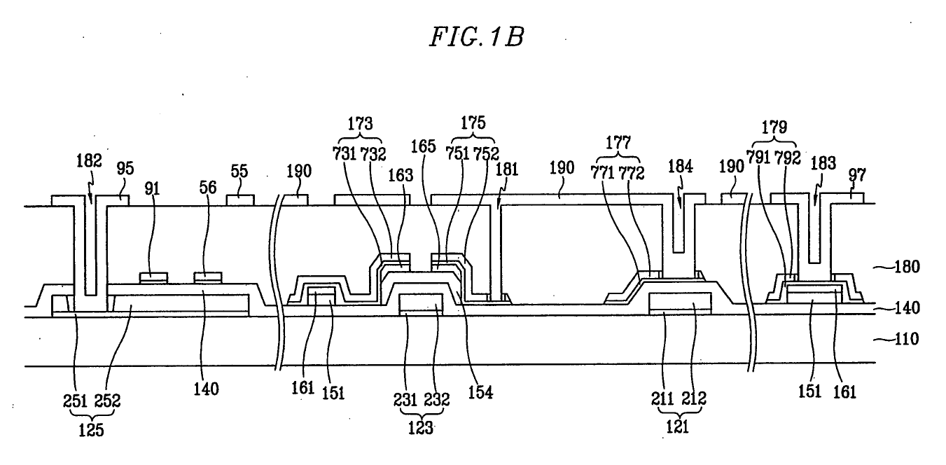

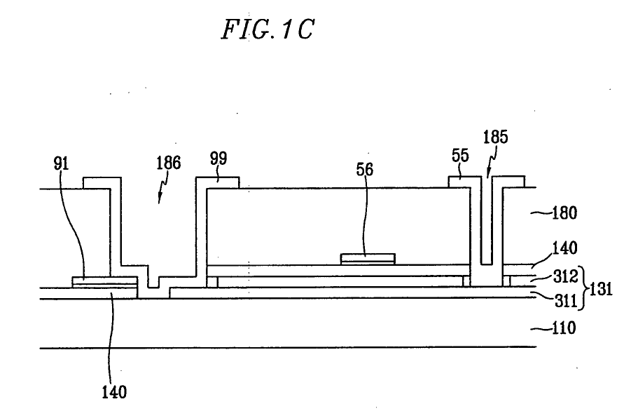

FIG. 1A is a layout view of a TFT array panel according to a first exemplary embodiment of the present invention, and FIGS. 1B and 1C are sectional views of the TFT array panel shown in FIG. 1A respectively taken along the lines IB-IB′ and IC-IC′;

As shown in FIGS. 1A to 1C, a plurality of gate lines 121 for transmitting gate signals and storage electrode lines 131 are formed on an insulating substrate 110.

The gate lines 121 and storage electrode lines 131 include two films having different physical characteristics, i.e., a lower film 211, 231, 251, and 311, and an upper film 165 212, 232, 252, and 312. The lower film 211, 231, 251, and 311 enhances adhesiveness of the gate lines 121 to the insulating substrate 110.

Each gate line 121 extends substantially in a transverse direction, and includes a plurality of portions forming a plurality of gate electrodes 123 and a plurality of projections 127 protruding downward. The gate line 121 has an end portion 125 having a large area for 170 connection with another layer, or an external driving circuit mounted on the substrate 110 or on another device such as a flexible printed circuit film (not shown) that may be attached to the substrate 110.

Each storage electrode line 131 extends substantially in a transverse direction, but it may have curved portions. The storage electrode line 131 has an end portion 135 having a 175 large area for connecting with other storage electrode lines 131. A storage line connecting bar 91, which will be described later, connects the storage electrode lines 131.

The gate lines 121 and storage electrode lines 131 are made of low resistivity metals including Al-containing metals such as Al and an Al alloy, and Ag-containing metals such as Ag and an Ag alloy; and materials such as Cr, Mo, a Mo alloy, Ta, and Ti, which have 180 good physical, chemical, and electrical contact characteristics. In particular, the lower film 211, 231, and 251 is preferably made of a material such as Cr, Mo, a Mo alloy, Ta, and Ti, which have good physical, chemical, and electrical contact characteristics, and the upper film 212, 232, and 252 is preferably made of a low resistivity metal including an Al-containing metal such as Al and an Al alloy, and an Ag-containing metal such as Ag and an Ag alloy. The gate lines 121 and storage electrode line 131 may be made of various other conductors.

A gate insulating layer 140, preferably made of silicon nitride (SiNx), is formed on the gate lines 121 and storage electrode lines 131.

A plurality of semiconductor stripes 151, preferably made of hydrogenated amorphous silicon (abbreviated to “a-Si”), are formed on the gate insulating layer 140. Each semiconductor stripe 151 extends substantially in the longitudinal direction and has a plurality of projections 154 branched out toward the gate electrodes 124. The width of each semiconductor stripe 151 becomes large near the gate lines 121 such that the semiconductor stripe 151 covers large areas of the gate lines 121.

A plurality of ohmic contact stripes 161 and ohmic contact islands 165, preferably made of silicide or n+ hydrogenated a-Si heavily doped with n type impurities, are formed on the semiconductor stripes 151. Each ohmic contact stripe 161 has a plurality of projections 163, and the projections 163 and the ohmic contact islands 165 are located in pairs on the projections 154 of the semiconductor stripes 151.

A plurality of data lines 171, a plurality of drain electrodes 175, and a plurality of storage capacitor conductors 177 are formed on the ohmic contacts 161 and 165 and the gate insulating layer 140.

The data lines 171 for transmitting data voltages extend substantially in the longitudinal direction and intersect the gate lines 121. Each data line 171 includes an end portion 179 for contact with another layer or an external device, and the end portion 179 may have an increased area for enhancing the contact.

A plurality of branches of each data line 171, which project toward the drain electrodes 175, form a plurality of source electrodes 173. Each pair of the source electrodes 173 and the drain electrodes 175 are separated from each other and are opposite each other with respect to a gate electrode 123.

The storage capacitor conductors 177 overlap the projections 127 of the gate lines 121.

The data lines 171 and drain electrode 175 include two films having different physical characteristics, a lower film 711, 731, 751, and 791, and an upper film 712, 732, 752, and 792. The lower film 711, 731, 751, and 791 enhances adhesiveness and/or contact characteristic of the data lines 171 to the ohmic contacts 161 and 163.

A storage line connecting bar 91 is formed on the gate insulating layer 140 and extends substantially in the longitudinal direction.

A repair bar 56 is formed on the gate insulating layer 140 and extends substantially in the longitudinal direction.

A passivation layer 180 is formed on the data lines 171, the drain electrodes 175, the storage capacitors conductor 177, and exposed portions of the semiconductor stripes 151, which are not covered with the data lines 171 and the drain electrodes 175. The passivation layer 180 is preferably made of a photosensitive organic material having a good flatness characteristic, or a low dielectric insulating material such as a-Si:C:O and a-Si:O:F formed by plasma enhanced chemical vapor deposition (PECVD). The passivation layer 180 may have a double-layered structure including a lower inorganic film preferably made of silicon nitride or silicon oxide, and an upper organic film to prevent direct contact between the semiconductor and organic material.

The passivation layer 180 has a plurality of contact holes 181, 182, 183, 184, 185, and 186 exposing the drain electrodes 175, the end portions 125 of the gate lines 121, the end portions 179 of the data lines 17 1, the storage conductors 177, the storage electrode lines 13 1, and the end portions 135 of the storage electrode lines 131, respectively.

A plurality of pixel electrodes 190 and a plurality of contact assistants 95 and 97, which are preferably made of ITO, amorphous ITO or IZO, are formed on the passivation layer 180.

The pixel electrodes 190 are physically and electrically connected to the drain electrodes 175 through the contact holes 181 and to the storage capacitor conductors 177 through the contact holes 184, such that the pixel electrodes 190 receive the data voltages from the drain electrodes 175 and transmit the received data voltages to the storage capacitor conductors 177.

The contact assistants 95 and 97 cover the contact holes 182 and 183 to be connected to the exposed end portions 125 of the gate lines 121 and the end portions 179 of the data lines 171 through the contact holes 182 and 183.

The pixel electrodes 190 overlap the data lines 171 and gate lines 121 in part to enhance the aperture ratio. However, the pixel electrodes 190 may also not overlap the data lines 171 and gate lines 121. Overlapping of the pixel electrodes 190 and the data lines 171 is allowed since the passivation layer 180 is made of a low dielectric insulating material to reduce cross talk between them.

A redundant connecting line 55 is formed on the passivation layer 180 and is connected to the storage electrode lines 131 through the contact holes 185.

A plurality of storage contact assistants 99 connecting the end portion 135 of the storage electrode lines 131 and the storage line connecting bar 91 are formed on the passivation layer 180.

The storage line connecting bar 91 is disposed on the peripheral area on which the end portions 135 of the storage electrode lines 131 are disposed.

The storage line connecting bar 91 is formed on the same layer as the data lines 171 and runs parallel with the data lines 171.

In the first exemplary embodiment, the gate lines 121 and storage electrode lines 131 are formed of the lower film 211, 231, 251, and 311 of Cr and the upper film 212, 232, 252, and 312 of Al. When Al contacts ITO (indium tin oxide), a contact defect is induced by an electrolysis effect. Therefore, the upper film 252 and 312 of Al is removed under the contact holes on which the contact assistants of ITO are disposed to prevent contact of Al with ITO.

The upper film 792, 752, and 772 of the end portions 179 of data lines 171, the drain electrodes 175, and the storage capacitor conductors 177 may also removed under the contact holes on which the contact assistants of ITO are disposed to prevent contact of Al with ITO.

When the upper film 252 and 312 is etched to be removed under the contact holes, portions of the upper film 252 and 312 around contact holes are etched to become undercuts. These undercuts make the storage contact assistants 99 easily disconnected by static electricity or an overflow of current. Disconnection of storage contact assistant 99 induces display defects such as the transverse stain.

To prevent such display defects, the redundant connecting line 55 connecting the storage electrode lines 131 is formed on the peripheral area of an LCD.

Therefore, when a storage electrode line 131 is disconnected from the storage line connecting bar 91 due to the undercut, the storage electrode line 131 is still connected to the redundant connecting line 55 to be connected to the other storage electrode lines 131. Accordingly, display defects such as the transverse stain are prevented.

Since the redundant connecting line 55 is formed on the peripheral area outside of the display area, the redundant connecting line 55 can do a good back-up job for the storage line connecting bar 91 without diminishing the aperture ratio.

However, the contact portion of the redundant connecting line 55 and the storage electrode line 131 may also have damage from a static electricity or an overflow of current as well as the contact portion of the storage line connecting bar 91 and the storage electrode line 13 1. In such a case, the transverse stain is shown.

As a preparation for such a case, the repair bar 56 is formed between the storage line connecting bar 91 and the redundant connecting line 55. The repair bar 56 is formed of the same material and is on the same layer as the data lines 171.

The repair bar 56 may be electrically connected to the storage electrode lines 131 through laser shorting when the contact portions of the redundant connecting line 55 and the storage electrode line and of the storage line connecting bar 91 and the storage electrode line 131 have concurrent damage.

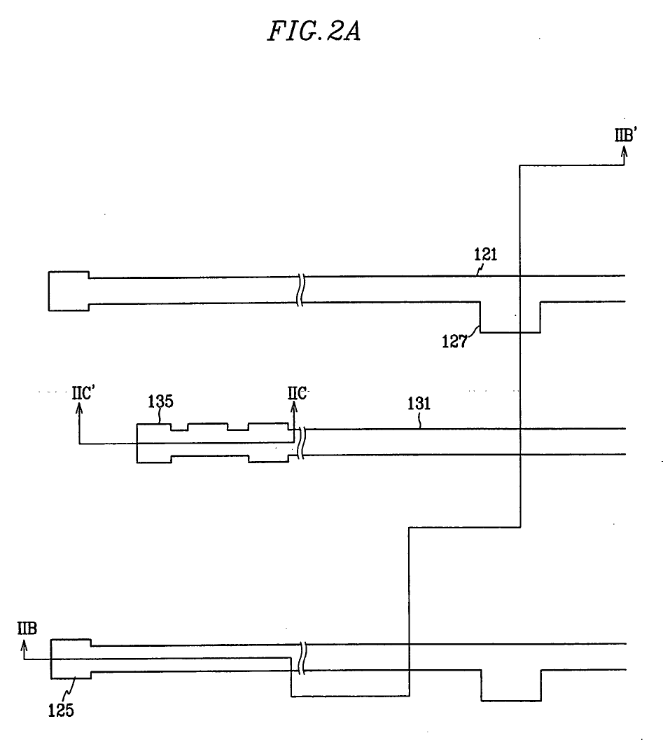

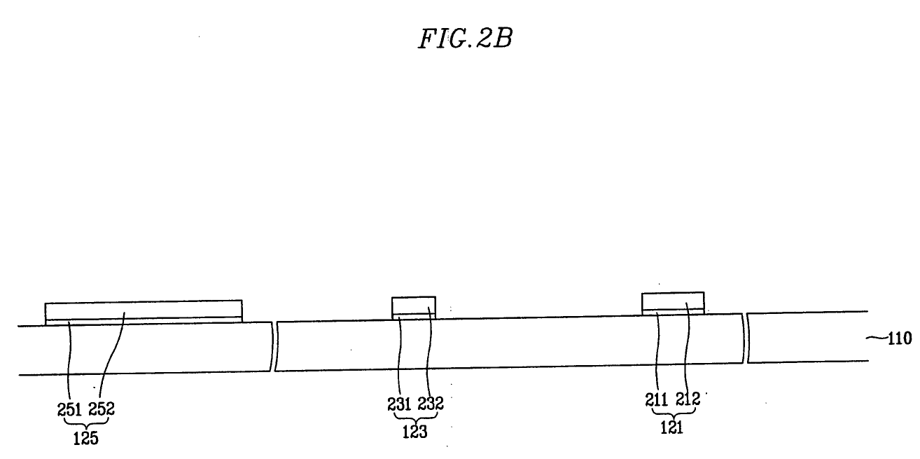

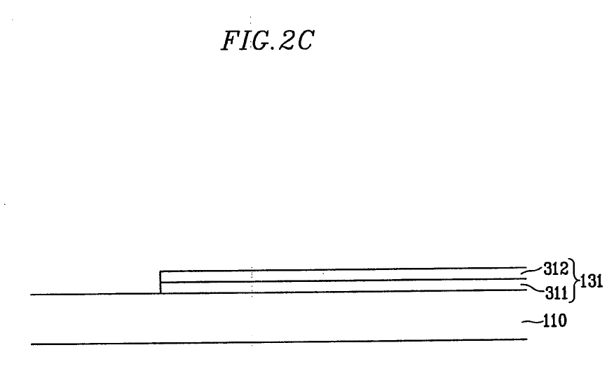

A method of manufacturing the TFT array panel shown in FIGS. 1A-1C according to an embodiment of the present invention will be now described in detail with reference to FIGS. 2A to 5C as well as FIGS. 1A-1C.

FIGS. 2A to 5C are sectional views of the TFT array panel shown in FIGS. 1A-1C in intermediate steps of a manufacturing method thereof according to an embodiment of the present invention

As shown in FIGS. 2A to 2C, two conductive films, i.e., a lower conductive film and an upper conductive film, are sputtered in sequence on an insulating substrate 110 such as transparent glass.

The upper conductive film and the lower conductive film are patterned in sequence by photo-etching with a photoresist pattern to form a plurality of gate lines 121 including a plurality of gate electrodes 123 and a plurality of projections 127.

Although the lower and the upper films may be separately etched under different conditions, they may be simultaneously etched preferably using an Al etchant including 8-15% CH₃COOH, 5-8% HNO₃, 50-60% H₃PO₄, and the remaining amount being H₂O.

The storage electrode lines 131 are formed along with the gate lines 121. Each storage electrode line 131 extends substantially in a transverse direction. The storage electrode line 131 has an end portion 135 having a large area for connecting with other storage electrode lines 131.

The lateral sides of the gate lines 121 and storage electrode lines 131 are inclined relative to a surface of the substrate 110, and the inclination angle thereof ranges about 30-80 degrees.

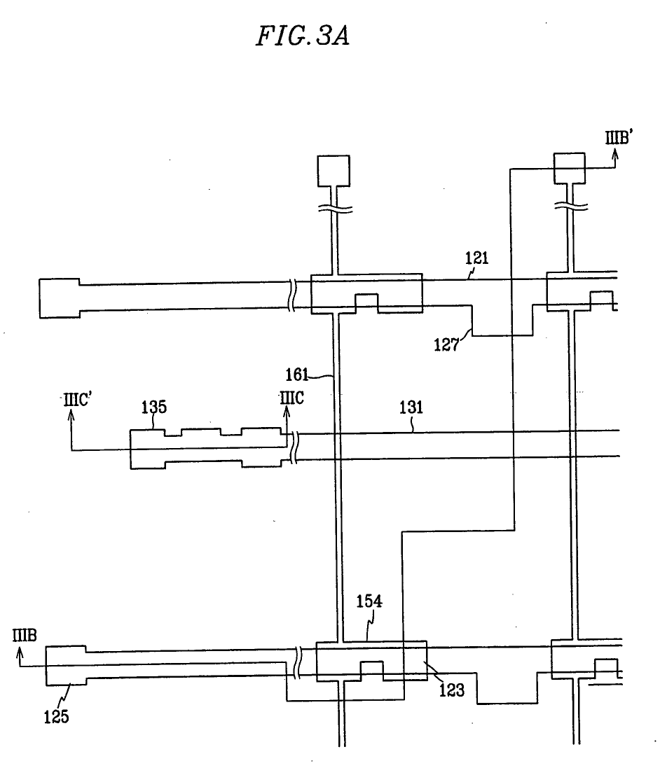

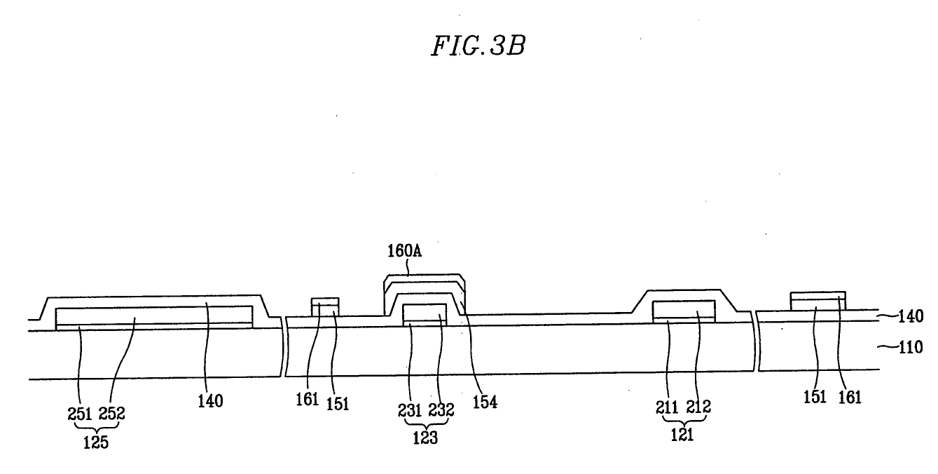

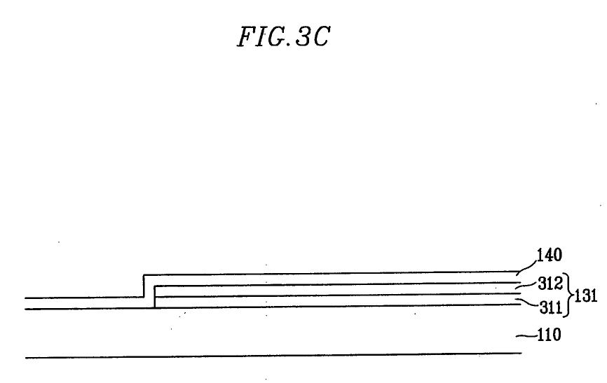

Referring to FIGS. 3A to 3C, after sequential deposition of a gate insulating layer 140, an intrinsic a-Si layer, and an extrinsic a-Si layer, the extrinsic a-Si layer and the intrinsic a-Si layer are photo-etched to form a plurality of extrinsic semiconductor stripes 161 and 160A and a plurality of intrinsic semiconductor stripes 151 including a plurality of projections 154 on the gate insulating layer 140.

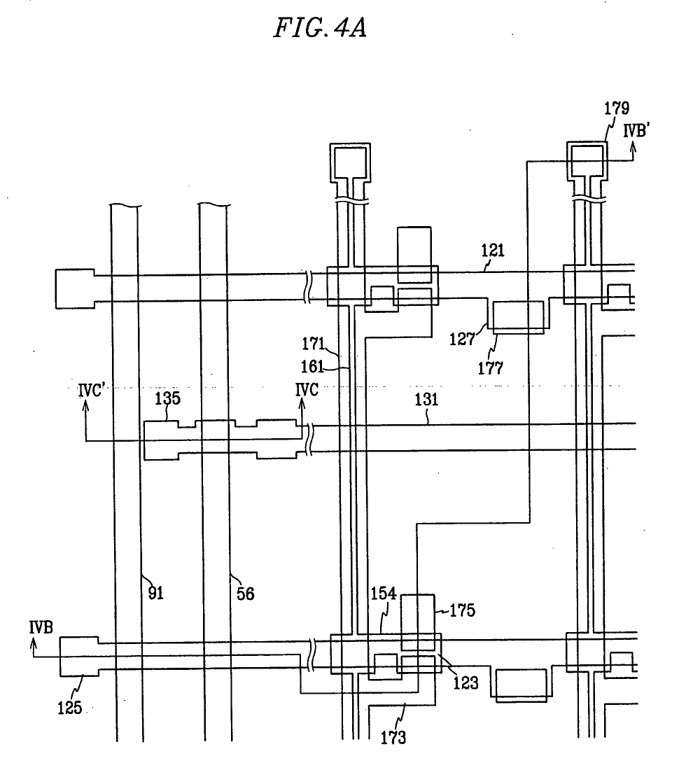

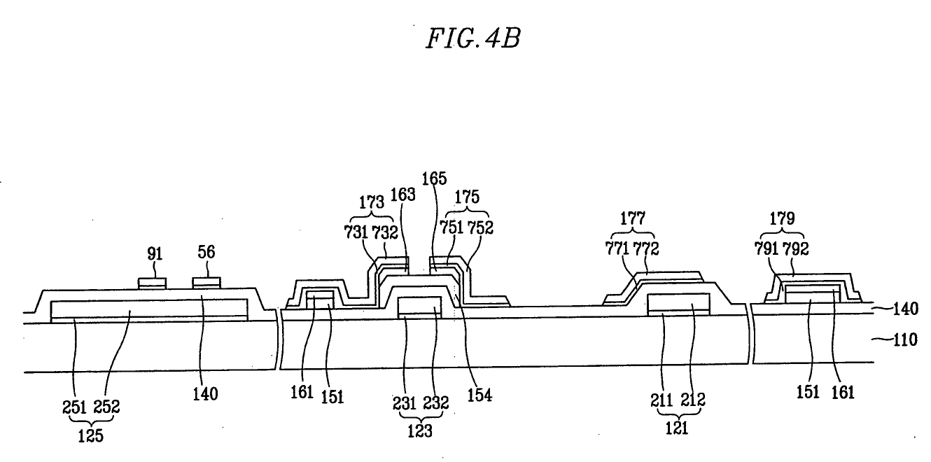

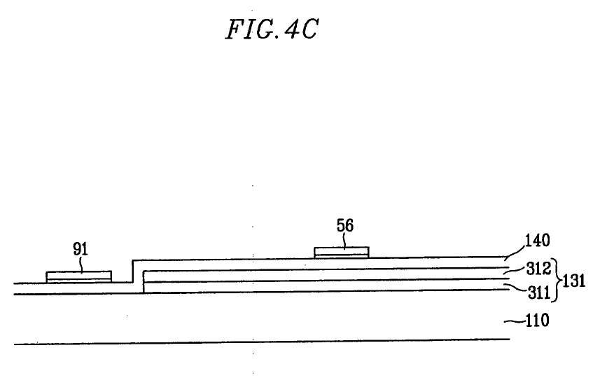

Referring to FIGS. 4A to 4C, a lower conductive film and a upper conductive film are sequentially sputtered and etched using a photoresist film (not shown) to form a plurality of data lines 171 including a plurality of source electrodes 173, a plurality of drain electrodes 175, and a plurality of storage capacitor conductors 177.

Before or after removing the photoresist film, portions of the extrinsic semiconductor stripes 164, which are not covered with the data lines 171, the drain electrodes 175, and the storage capacitor conductors 177, are removed by etching to complete a plurality of ohmic contact stripes 161 including a plurality of projections 163 and a plurality of ohmic contact islands 165 and to expose portions of the intrinsic semiconductor stripes 151.

Oxygen plasma treatment may follow thereafter in order to stabilize the exposed surfaces of the semiconductor stripes 151.

The storage line connecting bar 91 is formed along with the data lines 171.

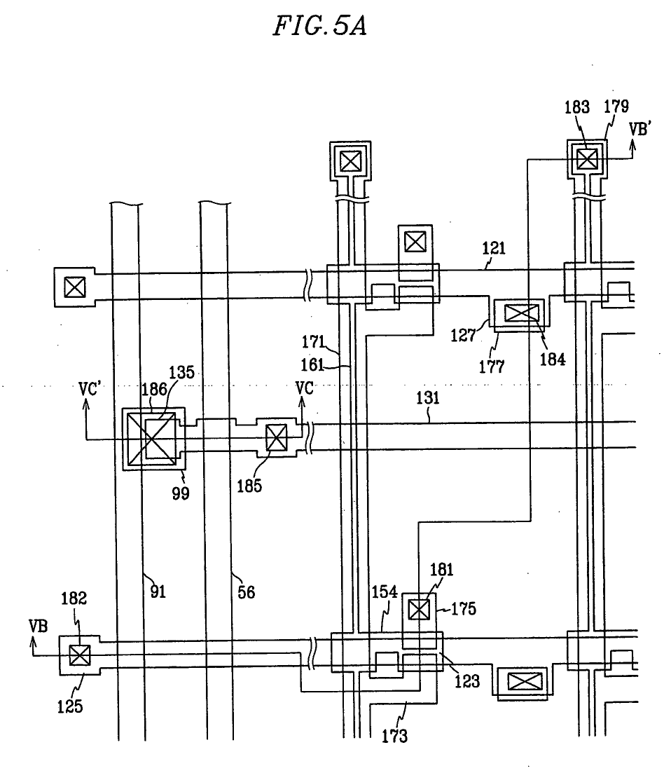

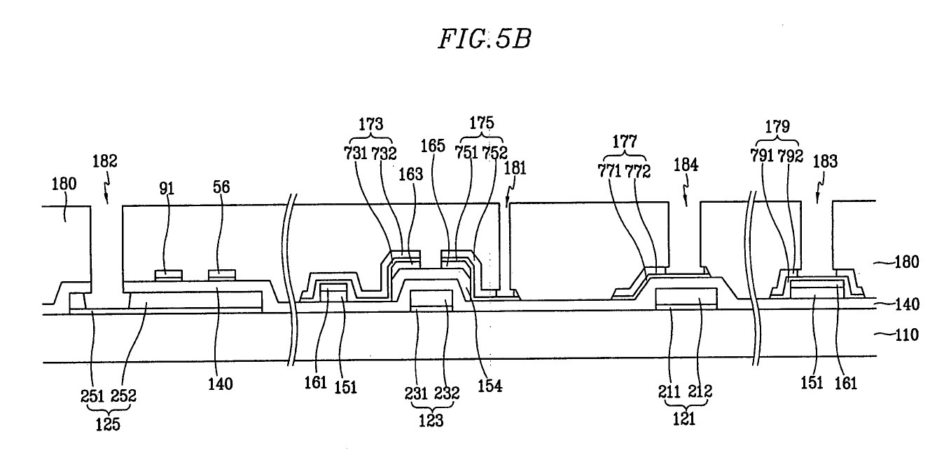

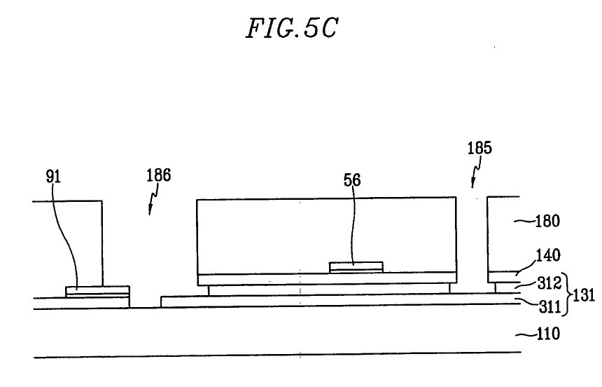

Referring to FIGS. 5A to SC, a passivation layer 180 made of insulating material is deposited and subjected to photo-etching to form a plurality of contact holes 181 to 184.

The contact holes 185 and 186 to expose the storage electrode lines 131 and the end portions 135 of the storage electrode lines 131 are also formed by etching the gate insulating layer 140 along with the passivation layer 180.

Next, a transparent conductive layer made of ITO, amorphous ITO or IZO is sputtered on the passivation layer 180 and photo-etched to form a plurality of pixel electrodes 190 and a plurality of contact assistants 95 and 97.

In addition, the redundant connecting line 55 is formed to be connected to the storage electrode lines 131 and the storage contact assistants 99 are formed to connect the storage line connecting bar 91 and the end portion 135 of the storage electrode lines 131.

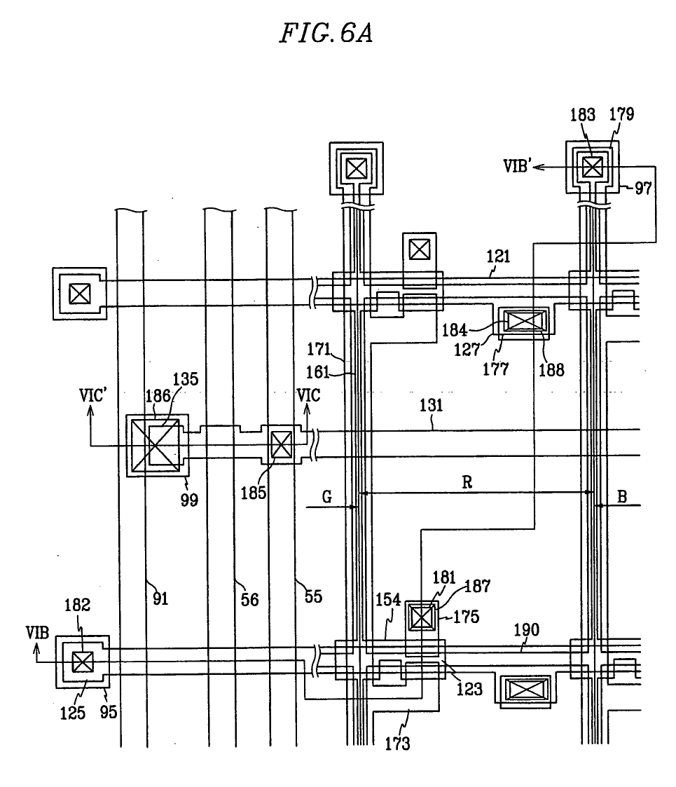

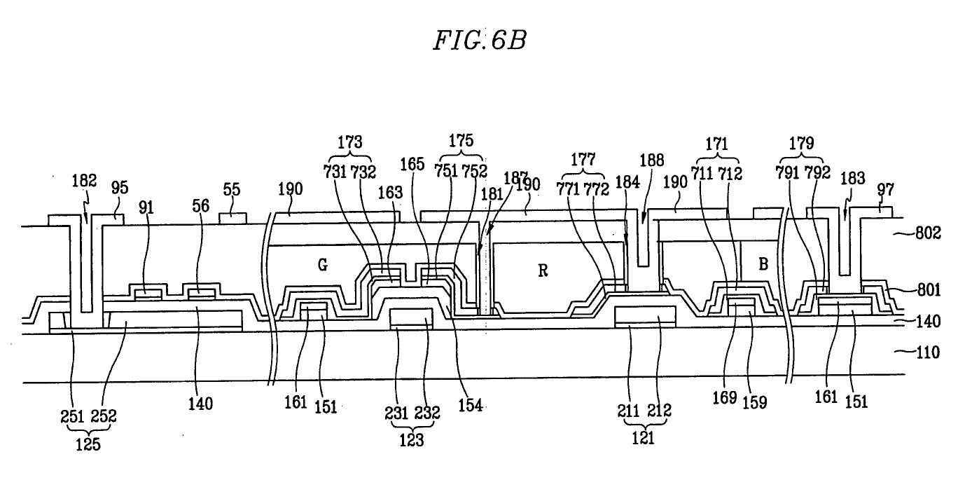

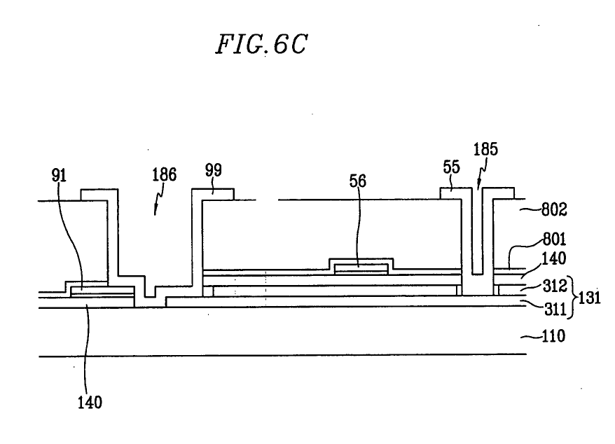

A TFT array panel for an LCD according to another embodiment of the present invention will be described in detail with reference to FIGS. 6A to 6C.

FIG. 6A is a layout view of a TFT array panel according to a second exemplary embodiment of the present invention. FIGS. 6B and 6C are sectional views of the TFT array panel shown in FIG. 6C respectively taken along the lines VIB-VIB′ and VIC-VIC′.

Referring to FIGS. 6A to 6C, an inorganic insulating layer 801 is formed on data lines 171, drain electrodes 175, and storage capacitor conductors.

Red, green, and blue color filters R, G, and B are formed on the inorganic insulating layer 801 and extend along pixel columns. The red, green, and blue color filters R, G, and B have contact holes 181 and 184 respectively exposing the drain electrodes 175 and the storage capacitor conductors 177.

The color filters R, G, and B are made of photo-sensitive materials having pigments. The photo-sensitive materials having pigments are coated, illuminated, and developed to form the color filters R, G, and B. At this time, the contact holes 181 and 184 are concurrently formed.

In FIGS. 6A and 6B, the color filers R, G, and B are illustrated as their boundaries coincide with each other on the data lines 171. However, the color filers R, G, and B may overlap each other by some width on the data lines 171 to block light leakage.

The color filters R, G, and B are not disposed on the end portions 125 and 179 of the gate lines 121 and data lines.

A passivation layer 802 is formed on the color filters R, G, and B. The passivation layer 802 is made of organic insulating materials such as acrylic materials, which having a low dielectric coefficient and a good leveling characteristic, or inorganic insulating materials such as SiOC and SiOF.

Here, the passivation layer 802 has contact holes 182 and 183 respectively exposing the end portions 125 and 179 of the gate lines 121 and data lines 171 and contact holes 187 and 188 respectively formed in the contact holes 181 and 184. The passivation layer 802 also has contact holes 185 and 186 respectively exposing storage electrode lines 131 and end portions 135 of the storage electrode lines 131.

A plurality of pixel electrodes 190 and a plurality of contact assistants 95 and 97, which are respectively connected to the drain electrodes 175, and the end portions 125 and 179 of the gate lines and data lines, are formed on the passivation layer 802.

The pixel electrodes 190 overlap the data lines 171 and gate lines 121 in part to enhance the aperture ratio. However, the pixel electrodes 190 may also not overlap the data lines 171 and gate lines 121. Overlapping of the pixel electrodes 190 and the data lines 171 is allowed since the passivation layer 802 is made of low dielectric insulating material to reduce cross talk between them.

A redundant connecting line 55 is formed on the passivation layer 802 and is connected to the storage electrode lines 131 through the contact holes 185.

A plurality of storage contact assistants 99 connecting the end portion 135 of the storage electrode lines 131 and the storage line connecting bar 91 are formed on the passivation layer 802.

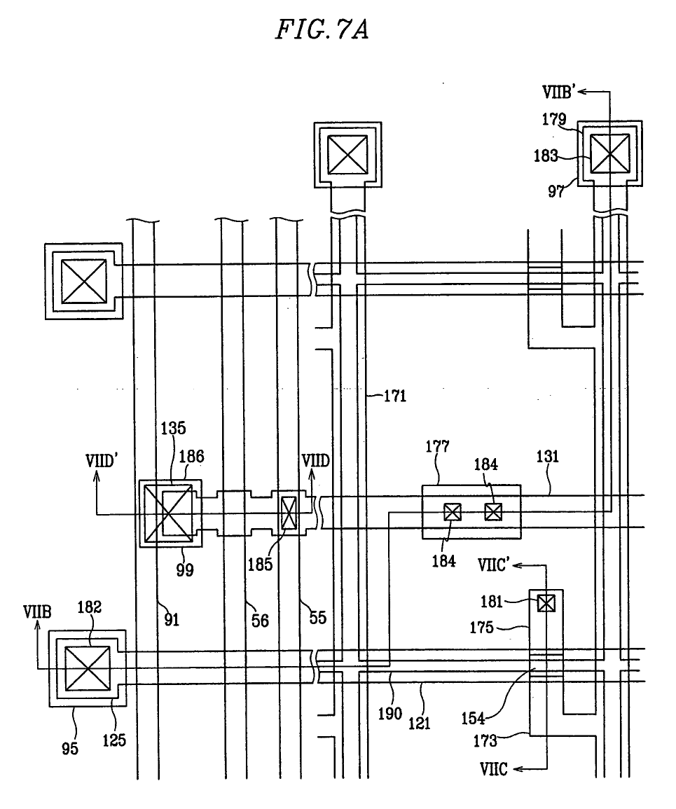

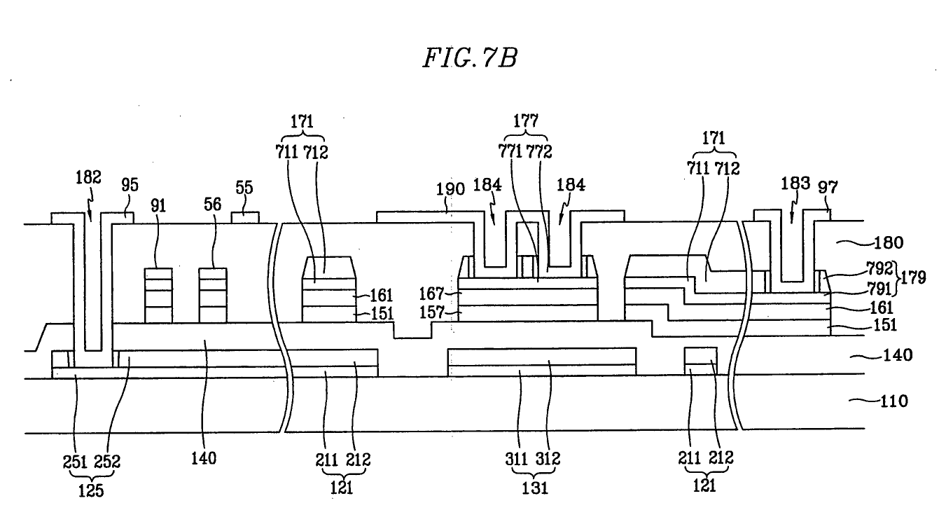

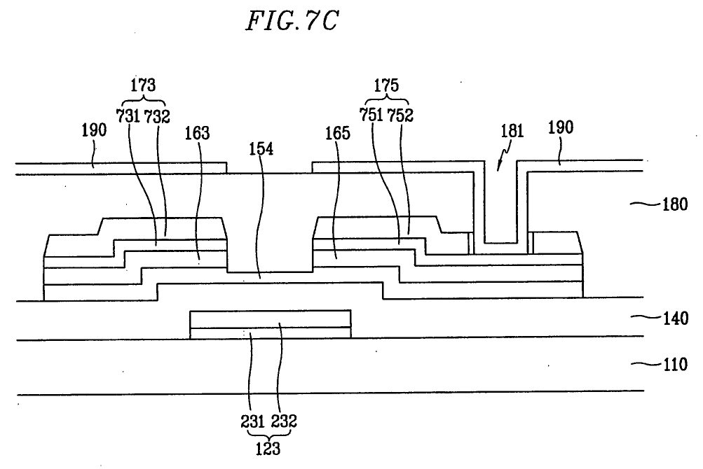

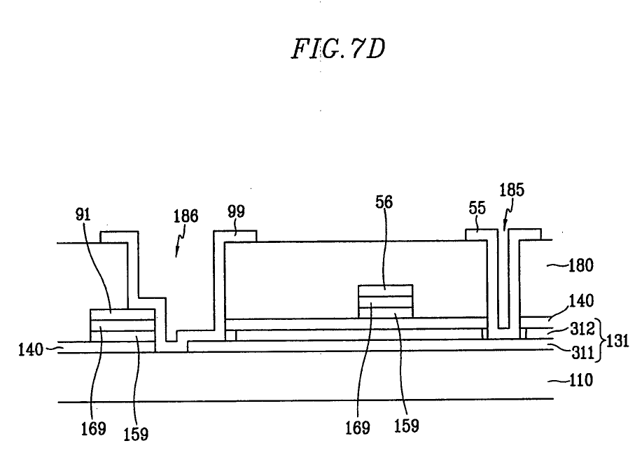

A TFT array panel for an LCD according to another embodiment of the present invention will be described in detail with reference to FIGS. 7A to 7D.

FIG. 7A is a layout view of a TFT array panel according to a third exemplary embodiment of the present invention. FIGS. 7B and 7C are sectional views of the TFT array panel shown in FIG. 7A respectively taken along the lines VIIB-VIIB′ and VIIC-VIIC′.

As shown in FIGS. 7A to 7C, a plurality of gate lines 121 for transmitting gate signals are formed on an insulating substrate 110.

The gate lines 121 include two films having different physical characteristics, i.e., a lower film 211, 231, 251, and 311, and an upper film 212, 232, 252, and 312. The lower film 211, 231, 251, and 311 enhances adhesiveness of the gate lines 121 to the insulating substrate 110.

Each gate line 121 extends substantially in a transverse direction, and includes a plurality of portions forming a plurality of gate electrodes 123. The gate line 121 has an end portion 125 having a large area for connection with another layer, or an external driving circuit mounted on the substrate 110 or on another device such as a flexible printed circuit film (not shown) that may be attached to the substrate 110.

Each storage electrode line 131 extends substantially in a transverse direction, but it may have curved portions. The storage electrode line 131 has an end portion 135 having a large area for connecting with other storage electrode lines 131. A storage line connecting bar 91 which will be described later connects the storage electrode lines 131.

The gate lines 121 and storage electrode lines 131 are made of low resistivity metals including Al-containing metals such as Al and an Al alloy, and Ag-containing metals such as Ag and an Ag alloy; and materials such as Cr, Mo, a Mo alloy, Ta, and Ti, which have good physical, chemical, and electrical contact characteristics. In particular, the lower film 211, 231, 251, and 311 is preferably made of materials such as Cr, Mo, a Mo alloy, Ta, and Ti, which have good physical, chemical, and electrical contact characteristics, and the upper film 212, 232, 252, and 312 is preferably made of low resistivity metals including Al-containing metals such as Al and an Al alloy, and Ag-containing metals such as Ag and an Ag alloy. The gate lines 121 and storage electrode line 131 may be made of other various conductors.

A gate insulating layer 140 preferably made of silicon nitride (SiNx) is formed on the gate lines 121 and storage electrode lines 131.

A plurality of semiconductor stripes 151 and islands 157 preferably made of a-Si are formed on the gate insulating layer 140. Each semiconductor stripe 151 extends substantially in the longitudinal direction, and has a plurality of projections 154 branched out toward the gate electrodes 124. The semiconductor islands 157 are disposed on the storage electrode lines 131.

A plurality of ohmic contact stripes 161 and islands 165 and 167 preferably made of silicide or n+ hydrogenated a-Si heavily doped with n type impurities are formed on the semiconductor stripes 151. Each ohmic contact stripe 161 has a plurality of projections 163, and the projections 163 and the ohmic contact islands 165 are located in pairs on the projections 154 of the semiconductor stripes 151. The other contact islands 167 are disposed on the semiconductor island 157.

A plurality of data lines 171, a plurality of drain electrodes 175, and a plurality of storage capacitor conductors 177 are formed on the ohmic contacts 161, 165, and 167.

The data lines 171 for transmitting data voltages extend substantially in the longitudinal direction and intersect the gate lines 121. Each data line 171 includes an end portion 179 for contact with another layer or an external device, and the end portion 179 may have an increased area for enhancing the contact.

The storage capacitor conductors 177 may be omitted.

The semiconductor stripes 151 have almost the same planar shapes as the data lines 171 and the drain electrodes 175, as well as the underlying ohmic contacts 161 and 165. However, the projections 154 of the semiconductor stripes 151 include some exposed portions, which are not covered with the data lines 171 and the drain electrodes 175, such as portions located between the source electrodes 173 and the drain electrodes 175, which form TFT channels.

A storage line connecting bar 91 is formed on the gate insulating layer 140 and extends substantially in the longitudinal direction.

A semiconductor bar 159 and ohmic contact bar 169 are formed under the storage line connecting bar 91 to have substantially the same planar pattern as the storage line connecting bar 91.

A repair bar 56 is formed on the gate insulating layer 140 and extends substantially in the longitudinal direction. A semiconductor bar 159 and ohmic contact bar 169 are formed under the repair bar 91 to have substantially the same planar pattern as the repair bar 56

A passivation layer 180 is formed on the data lines 171, the drain electrodes 175, the storage capacitors conductor 177, and exposed portions of the semiconductor stripes 151, which are not covered with the data lines 171 and the drain electrodes 175. The passivation layer 180 has a plurality of contact holes 181, 182, 183, 184, 185, and 186 exposing the drain electrodes 175, the end portions 125 of the gate lines 121, the end portions 179 of the data lines 171, the storage conductors 177, the storage electrode lines 131, and the end portions 135 of the storage electrode lines 131, respectively.

A plurality of pixel electrodes 190 and a plurality of contact assistants 95 and 97, which are preferably made of ITO, amorphous ITO or IZO, are formed on the passivation layer 180.

The pixel electrodes 190 are physically and electrically connected to the drain electrodes 175 through the contact holes 181 and to the storage capacitor conductors 177 through the contact holes 184, such that the pixel electrodes 190 receive the data voltages from the drain electrodes 175 and transmit the received data voltages to the storage capacitor conductors 177.

The contact assistants 95 and 97 cover the contact holes 182 and 183 to be connected to the exposed end portions 125 of the gate lines 121 and the end portions 179 of the data lines 171 through the contact holes 182 and 183.

The pixel electrodes 190 overlap the data lines 171 and gate lines 121 in part to enhance aperture ratio. However, the pixel electrodes 190 may also not overlap the data lines 171 and gate lines 121. Overlapping of the pixel electrodes 190 and the data lines 171 is allowed since the passivation layer 180 is made of a low dielectric insulating material to reduce cross talk between them.

A redundant connecting line 55 is formed on the passivation layer 180 and is connected to the storage electrode lines 131 through the contact holes 185.

A plurality of storage contact assistants 99 connecting the end portion 135 of the storage electrode lines 131 and the storage line connecting bar 91 are formed on the passivation layer 180.

The storage line connecting bar 91 is disposed on the peripheral area on which the end portions 135 of the storage electrode lines 131 are disposed.

The storage line connecting bar 91 is formed on the same layer as the data lines 171 and runs parallel with the data lines 171.

In the third exemplary embodiment, the gate lines 121 and storage electrode lines 131 are formed of the lower film 211, 231, 251, and 311 of Cr and the upper film 212, 232, 252, and 312 of Al. When Al contacts ITO (indium tin oxide), a contact defect is induced by an electrolysis effect. Therefore, the upper film 212 of Al is removed under the contact hole on which the contact assistants of ITO are disposed to prevent contact of Al with ITO.

The upper film 792, 752, and 772 of the end portions 179 of data lines 171, the drain electrodes 175, and the storage capacitor conductors 177 may also removed under the contact holes on which the contact assistants of ITO are disposed to prevent contact of Al with ITO.

When the upper film 212 is etched to be removed under the contact holes, portions of the upper film 212 around contact holes are etched to become undercuts. These undercuts make the storage contact assistants 99 easily disconnected by static electricity or an overflow of current. Disconnection of storage contact assistant 99 induces display defects such as the transverse stain.

To prevent such display defects, the redundant connecting line 55 connecting the storage electrode lines 131 is formed on the peripheral area of an LCD.

Therefore, when a storage electrode line 131 is disconnected from the storage line connecting bar 91 due to the undercut, the storage electrode line 131 is still connected to the redundant connecting line 55 to be connected to the other storage electrode lines 131. Accordingly, display defects such as the transverse stain is prevented.

Since the redundant connecting line 55 is formed on the peripheral area outside of the display area, the redundant connecting line 55 can do a good back-up job for the storage line connecting bar 91 without diminishing the aperture ratio.

However, the contact portion of the redundant connecting line 55 and the storage electrode line 131 may also have damage from static electricity or an overflow of current, as can the contact portion of the storage line connecting bar 91 and the storage electrode line 131. In such a case, the transverse stain is shown.

As a preparation for such a case, the repair bar 56 is formed between the storage line connecting bar 91 and the redundant connecting line 55. The repair bar 56 is formed of the same material and is on the same layer as the data lines 171.

The repair bar 56 may be electrically connected to the storage electrode lines 131 through laser shorting when the contact portions of the redundant connecting line 55 and the storage electrode line and of the storage line connecting bar 91 and the storage electrode line 131 have concurrent damage.

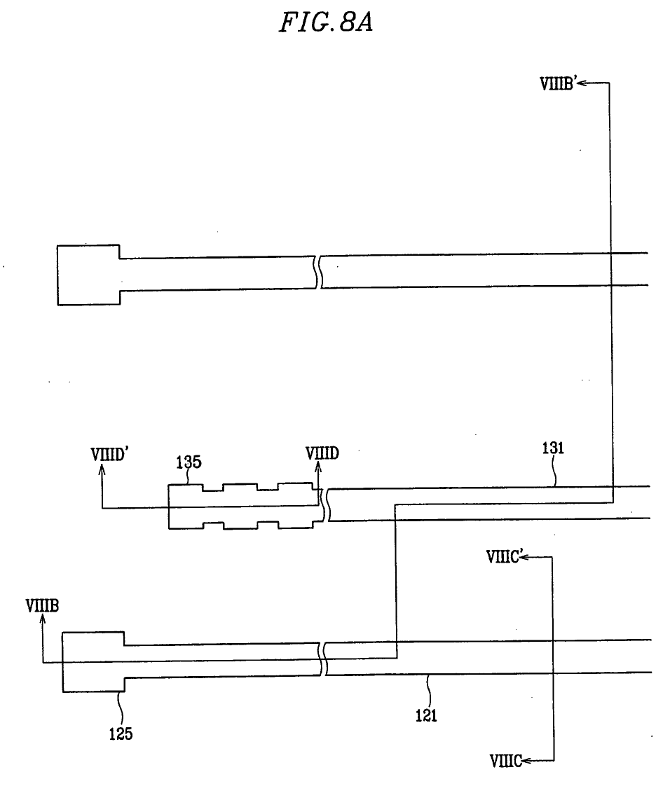

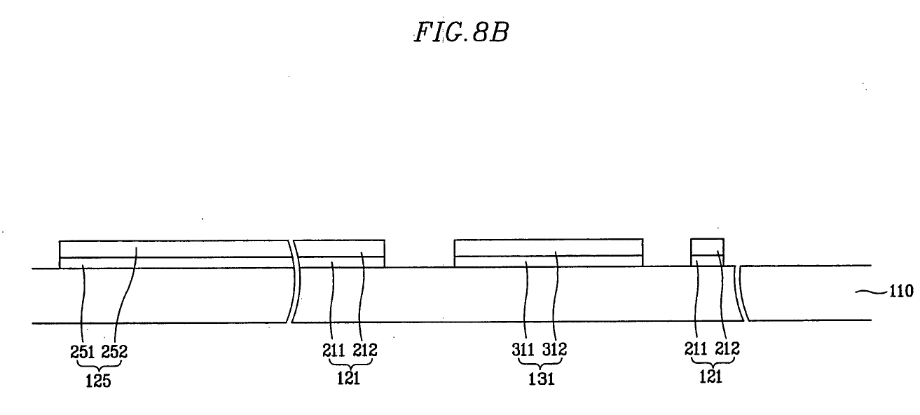

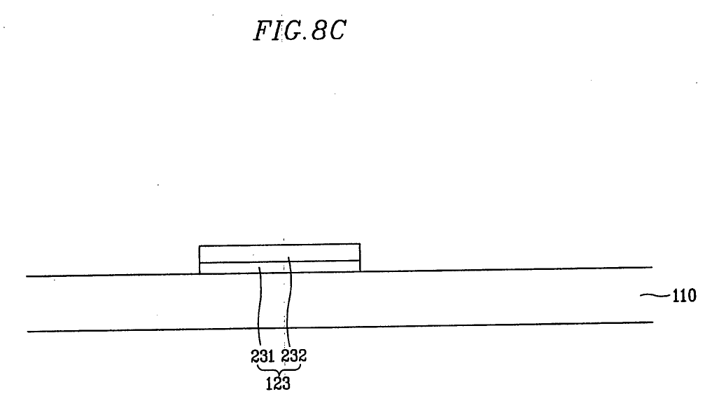

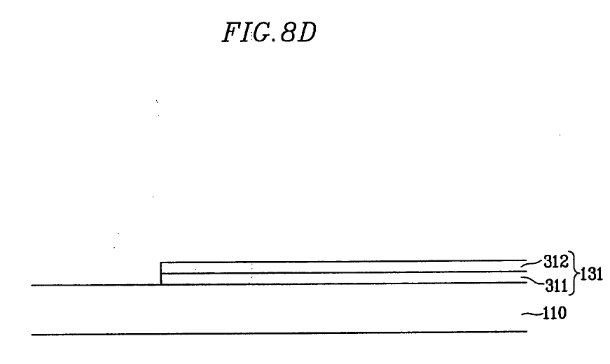

A method of manufacturing the TFT array panel shown in FIGS. 1A-1C according to an embodiment of the present invention will be now described in detail with reference to FIGS. 8A to 12D.

As shown in FIGS. 8A to 8D, two conductive films, i.e., a lower conductive film and an upper conductive film, are sputtered in sequence on an insulating substrate 110 such as transparent glass.

The upper conductive film and the lower conductive film are patterned in sequence by photo-etching with a photoresist pattern to form a plurality of gate lines 121 including a plurality of gate electrodes 123.

Although the lower and the upper films may be separately etched under different conditions, they may also be simultaneously etched, preferably using an Al etchant including 8-15% CH₃COOH, 5-8% HNO₃, 50-60% H₃PO₄, and the balance H₂O.

The storage electrode lines 131 are formed along with the gate lines 121. Each storage electrode line 131 extends substantially in a transverse direction. The storage electrode line 131 has an end portion 135 having a large area for connecting with other storage electrode lines 131.

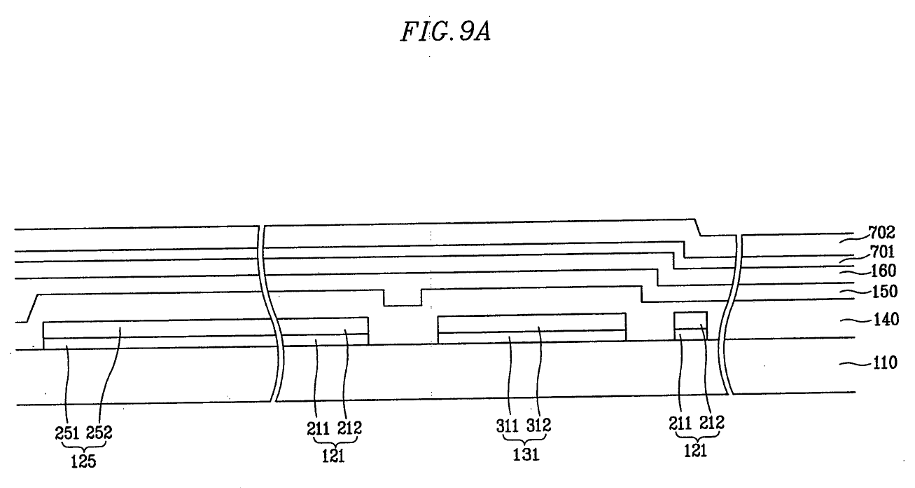

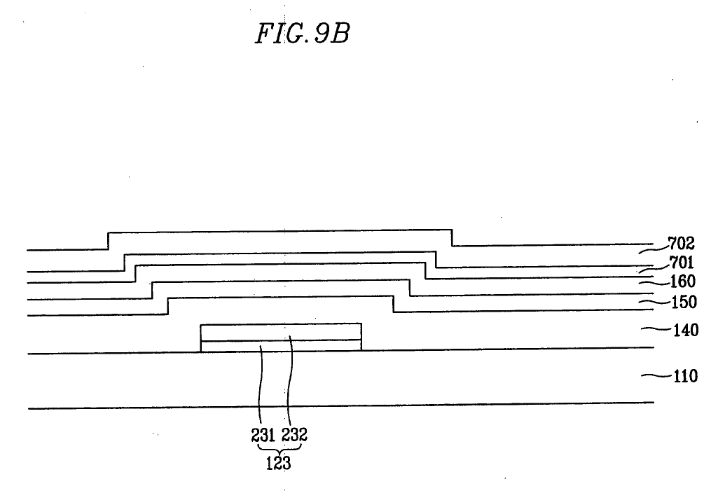

Referring to FIGS. 9A to 9D, after sequential deposition of a gate insulating layer 140, an intrinsic a-Si layer 150, and an extrinsic a-Si layer 160 using chemical vapor deposition, lower and upper conductive films 701 and 702 are deposited to form the data lines 171, drain electrodes 175, and storage capacitor conductors 177.

A photoresist film with a thickness of about 1-2 microns is coated on the upper conductive film 702.

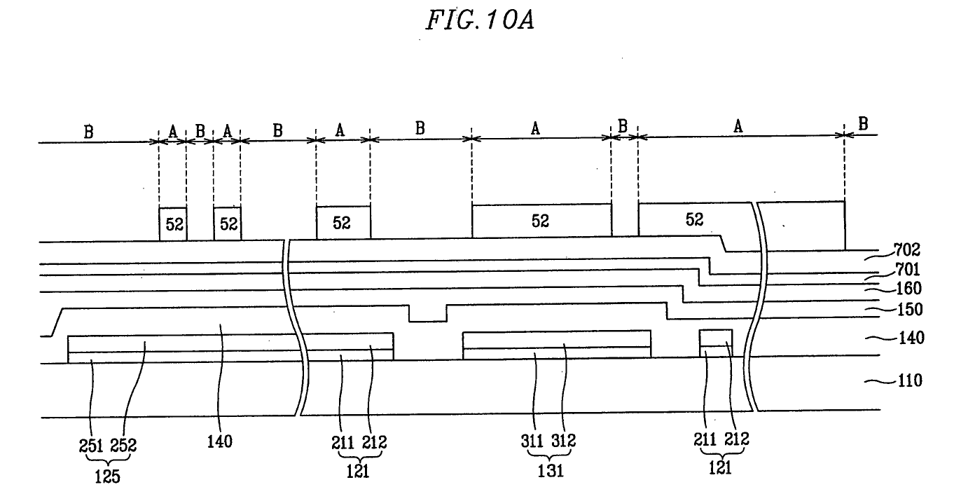

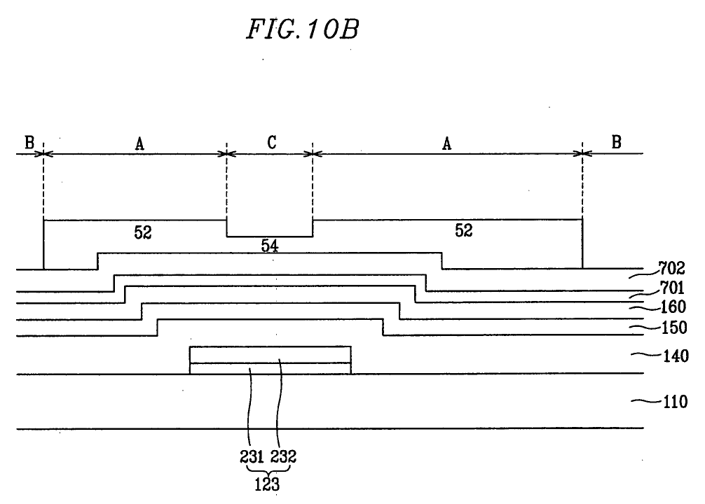

Referring to FIGS. 10A to 10B, the photoresist film is exposed to light through an exposure mask (not shown), and is developed such that the developed photoresist has a position-dependent thickness. The photoresist shown in FIGS. 10A and 10B includes a plurality of first to third portions with decreased thickness. The first portions located on wire areas A and the second portions located on channel areas C are indicated by reference numerals 52 and 54, respectively, and no reference numeral is assigned to the third portions located on remaining areas B since they have substantially zero thickness to expose underlying portions of the upper conductive layer 702. The thickness ratio of the second portions 54 to the first portions 52 is adjusted depending upon the process conditions in the subsequent process steps. It is preferable that the thickness of the second portions 54 is equal to or less than half of the thickness of the first portions 52, and in particular, equal to or less than 4,000 Å.

The position-dependent thickness of the photoresist is obtained by several techniques, for example, by providing translucent areas on the exposure mask as well as transparent areas and light-blocking opaque areas. The translucent areas may have a slit pattern, a lattice pattern, or a thin film(s) with intermediate transmittance or intermediate thickness.

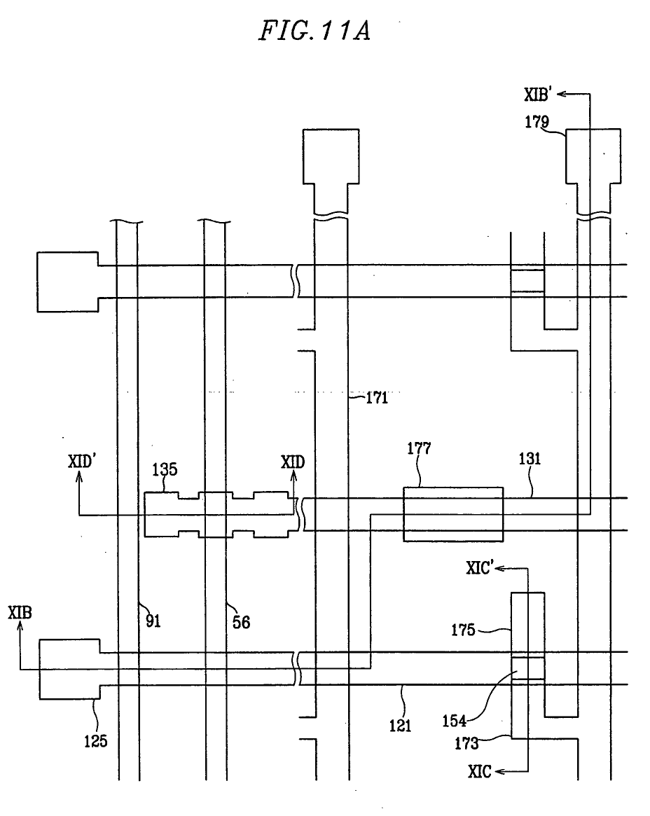

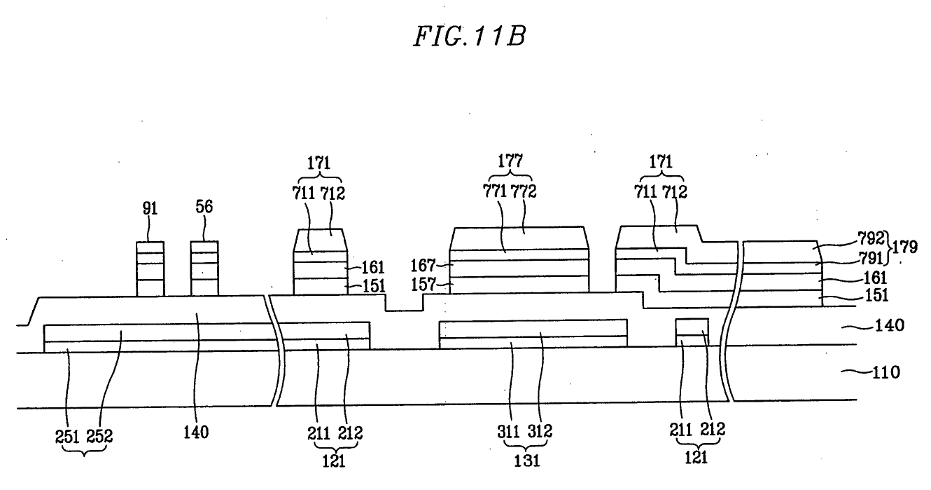

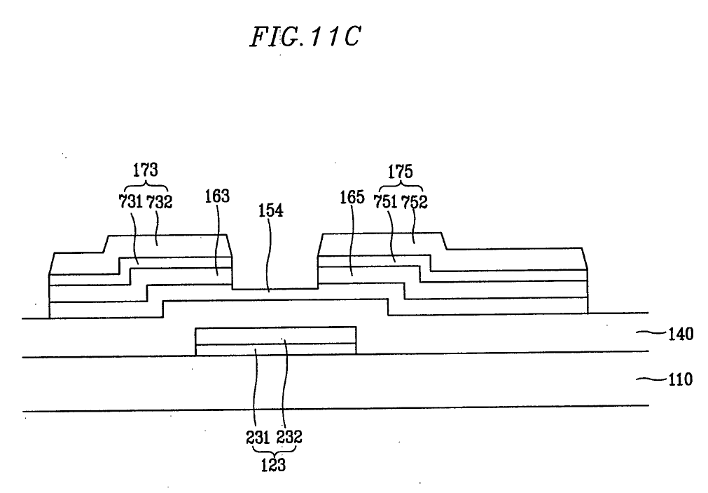

The different thickness of the photoresist 52 and 54 enables selective etching of the underlying layers when using suitable process conditions. Therefore, a plurality of data lines 171 including a plurality of source electrodes 173 and a plurality of drain electrodes 175, as well as a plurality of ohmic contact stripes 161 including a plurality of projections 163, a plurality of ohmic contact islands 165, and a plurality of semiconductor stripes 151 including a plurality of projections 154, are obtained as shown in FIGS. 11A-11D by a series of etching steps.

For descriptive purposes, portions of the lower and upper conductive films 701 and 702, the extrinsic a-Si layer 160, and the intrinsic a-Si layer 150 on the wire areas A are called first portions, portions of the lower and upper conductive films 701 and 702, the extrinsic a-Si layer 160, and the intrinsic a-Si layer 150 on the channel areas C are called second portions, and portions of the lower and upper conductive films 701 and 702, the extrinsic a-Si layer 160, and the intrinsic a-Si layer 150 on the remaining areas B are called third portions.

An exemplary sequence of forming such a structure is as follows:

(1) Removal of third portions of the lower and upper conductive films 701 and 702, the extrinsic a-Si layer 160, and the intrinsic a-Si layer 150 on the wire areas A;

(2) Removal of the second portions 54 of the photoresist;

(3) Removal of the second portions of the lower and upper conductive films 701 and 702 and the extrinsic a-Si layer 160 on the channel areas C; and

(4) Removal of the first portions 52 of the photoresist.

Another exemplary sequence is as follows:

(1) Removal of the third portions of the lower and upper conductive films 701 and 702;

(2) Removal of the second portions 54 of the photoresist;

(3) Removal of the third portions of the extrinsic a-Si layer 160 and the intrinsic a-Si layer 150;

(4) Removal of the second portions of the lower and upper conductive films 701 and 702;

(5) Removal of the first portions 52 of the photoresist; and

(6) Removal of the second portions of the extrinsic a-Si layer 160.

The first example is described in detail.

Referring to FIGS. 11A and 11D, the exposed third portions of the lower and upper conductive films 701 and 702 on the remaining areas B are removed by wet etching or dry etching to expose the underlying third portions of the extrinsic a-Si layer 160. An Al-containing metal film is preferably wet etched preferably using an Al etchant including 8-15% CH₃COOH, 5-8% HNO₃, 50-60% H₃PO₄, and the balance H₂O.

Successively, the third portions of the extrinsic a-Si layer 160 on the areas B and of the intrinsic a-Si layer 150 are removed preferably by dry etching, and the second portions 54 of the photoresist are removed to expose the second portions of the lower and upper conductive films 701 and 702. The removal of the second portions 54 of the photoresist are performed either simultaneously with or independent from the removal of the third portions of the extrinsic a-Si layer 160 and of the intrinsic a-Si layer 150. Residue of the second portions 54 of the photoresist remained on the channel areas C is removed by ashing.

The semiconductor stripes 151 are completed in this step. At this step, the ohmic contact stripes and islands 161 and 165 are connected to each other. This connected ohmic contact stripes and islands 161 and 165 will be called “extrinsic semiconductor stripes.”

The upper and lower conductive films 701 and 702 and the extrinsic a-Si stripes on the channel areas C as well as the first portion 52 of the photoresist are removed.

In this case, the exposed portions of the extrinsic semiconductor stripes are removed using the data lines 171, the drain electrodes 175, and the storage capacitor conductors 177 as an etch mask after removing the photoresist film.

Top portions of the projections 154 of the intrinsic semiconductor stripes 151 on the channel areas C may be removed to cause thickness reduction, and the first portions 52 of the photoresist are etched to a predetermined thickness.

In this way, the upper and lower conductive films 701 and 702 are divided into a data line 171 and a plurality of drain electrodes 175 to be completed, and each extrinsic semiconductor stripe is divided into an ohmic contact stripe 161 and a plurality of ohmic contact islands 165 to be completed.

In this step, the storage line connecting bar 91 and the repair bar 56 are formed along with the data lines 171. The repair bar 56 may be electrically connected to the storage electrode lines 131 through laser shorting when needed.

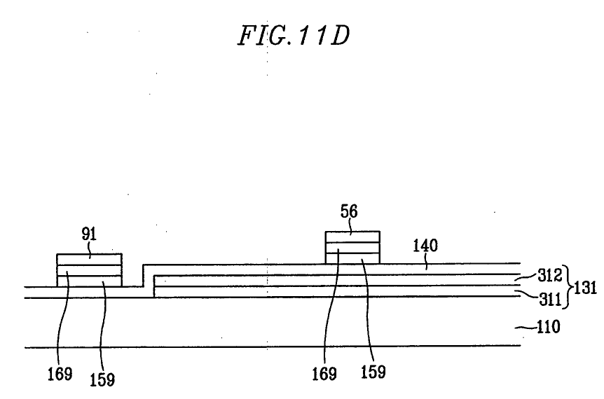

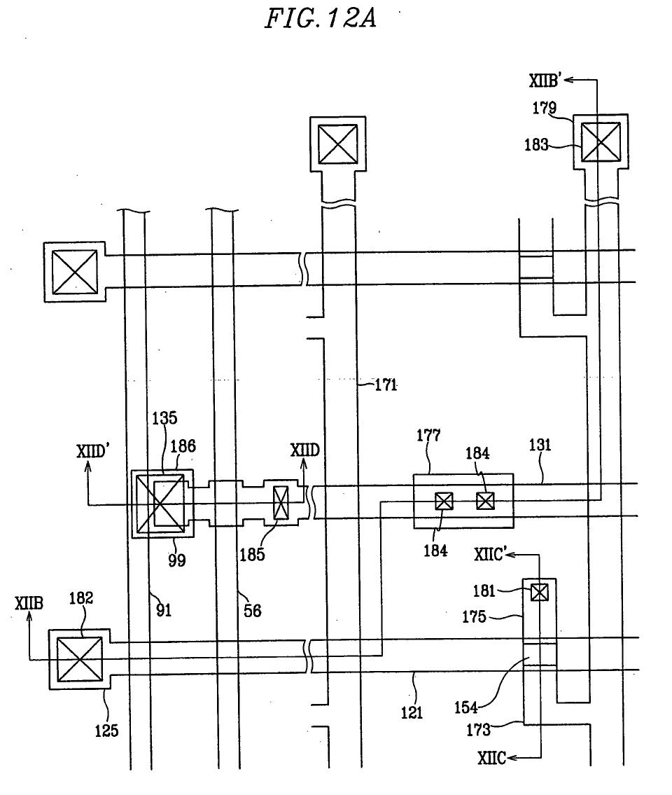

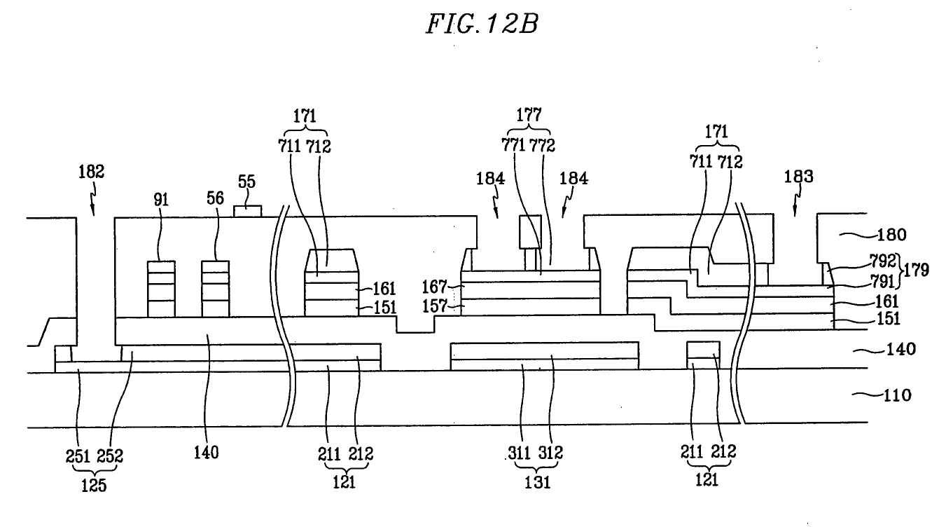

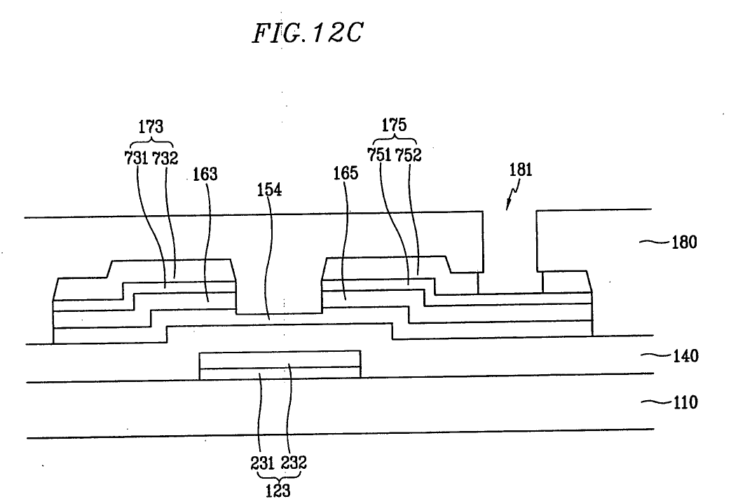

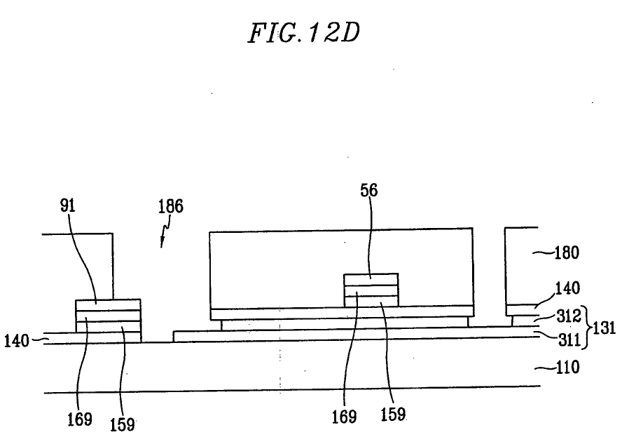

Referring to FIGS. 12A to 12C, a passivation layer 180 made of insulating material is deposited and subjected to photo-etching to form a plurality of contact holes 181 to 184.

The contact holes 185 and 186 to expose the storage electrode lines 131 and the end portions 135 of the storage electrode lines 131 are also formed by etching the gate insulating layer 140 along with the passivation layer 180.

Next, a transparent conductive layer made of ITO, amorphous ITO or IZO is sputtered on the passivation layer 180 and photo-etched to form a plurality of pixel electrodes 190 and a plurality of contact assistants 95 and 97.

In addition, the redundant connecting line 55 is formed to be connected to the storage electrode lines 131, and the storage contact assistants 99 are formed to connect the storage line connecting bar 91 and the end portion 135 of the storage electrode lines 131.

The pixel electrodes 190 are physically and electrically connected to the drain electrodes 175 through the contact holes 181 and to the storage capacitor conductors 177 through the contact holes 184, such that the pixel electrodes 190 receive the data voltages from the drain electrodes 175 and transmit the received data voltages to the storage capacitor conductors 177.

The contact assistants 95 and 97 cover the contact holes 182 and 183 to be connected to the exposed end portions 125 of the gate lines 121 and the end portions 179 of the data lines 171 through the contact holes 182 and 183.

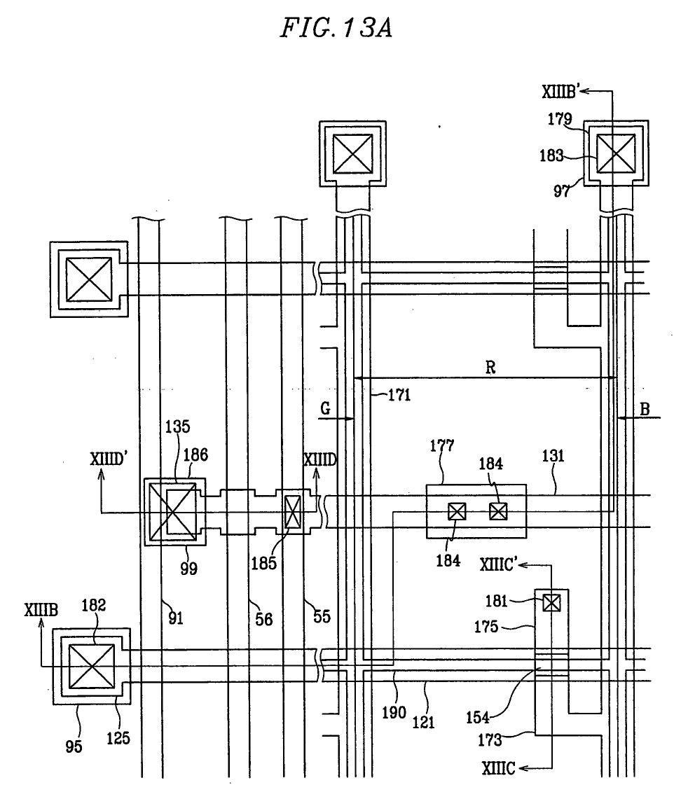

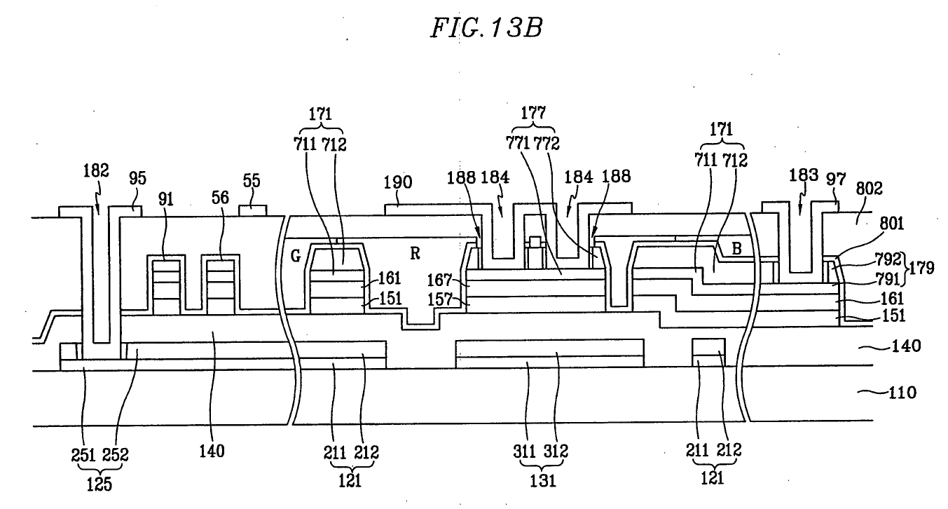

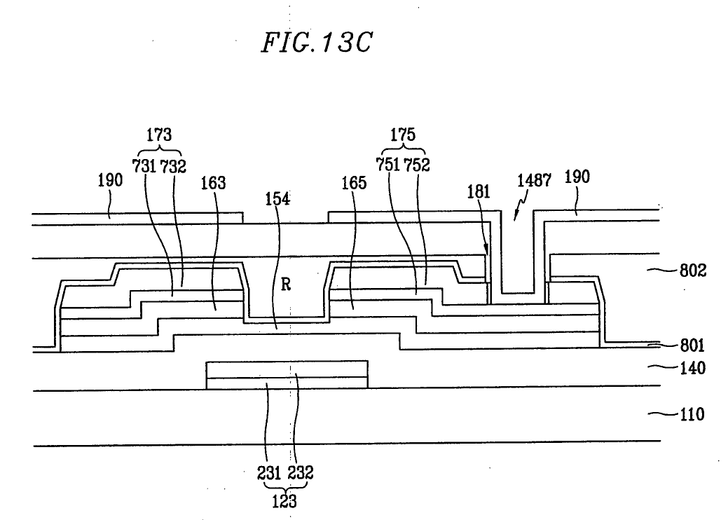

FIG. 13A is a layout view of a TFT array panel according to a fourth exemplary embodiment of the present invention. FIGS. 13B to 13D are sectional views of the TFT array panel shown in FIG. 13A respectively taken along the lines XIIIB-XIIIB′, XIIIC-XIIIC′, and XIIID-XIIID′.

The exemplary embodiment of the present invention shown in FIGS. 13A to 13D as the same structure of the gate lines 121 and storage electrode lines 131; the gate insulating layer 140; the semiconductor stripes 151 and islands 157; the ohmic contact stripes 161 and islands 165 and 167; and the data lines 171, drain electrodes 175, and storage capacitor conductors 177 as the exemplary embodiment of the present invention shown in FIGS. 7A to 7D.

An inorganic insulating layer 801 is formed on data lines 171, drain electrodes 175, and storage capacitor conductors 177.

Red, green, and blue color filters R, G, and B are formed on the inorganic insulating layer 801 and extend along pixel columns. The red, green, and blue color filters R, G, and B have contact holes 181 and 184 respectively exposing the drain electrodes 175 and the storage capacitor conductors 177.

The color filters R, G, and B are made of photo-sensitive materials having pigments. The photo-sensitive materials having pigments are coated, illuminated, and developed to form the color filters R, G, and B. At this time, the contact holes 181 and 184 are concurrently formed.

In FIGS. 13A to 13D, the color filers R, G, and B are illustrated as their boundaries coincide with each other on the data lines 171. However, the color filers R, G, and B may also overlap each other by some width on the data lines 171 to block light leakage.

The color filters R, G, and B are not disposed on the end portions 125 and 179 of the gate lines 121 and data lines.

A passivation layer 802 is formed on the color filters R, G, and B. The passivation layer 802 is made of organic insulating materials such as acrylic materials which have a low dielectric coefficient and a good leveling characteristic, or inorganic insulating materials such as SiOC and SiOF.

Here, the passivation layer 802 has contact holes 182 and 183 respectively exposing the end portions 125 and 179 of the gate lines 121 and data lines 171 and contact holes 187 and 188 respectively formed in the contact holes 181 and 184. The passivation layer 802 also has contact holes 185 and 186 respectively exposing storage electrode lines 131 and end portions 135 of the storage electrode lines 131.

A plurality of pixel electrodes 190 and a plurality of contact assistants 95 and 97, which are respectively connected to the drain electrodes 175, the end portions 125 and 179 of the gate lines and data lines are formed on the passivation layer 802.

The pixel electrodes 190 overlap the data lines 171 and gate lines 121 in part to enhance aperture ratio. However, the pixel electrodes 190 may also not overlap the data lines 171 and gate lines 121. Overlapping of the pixel electrodes 190 and the data lines 171 is allowed since the passivation layer 802 is made of a low dielectric insulating material to reduce cross talk between them.

A redundant connecting line 55 is formed on the passivation layer 802 and is connected to the storage electrode lines 131 through the contact holes 185.

A plurality of storage contact assistants 99 connecting the end portion 135 of the storage electrode lines 131 and the storage line connecting bar 91 are formed on the passivation layer 802.

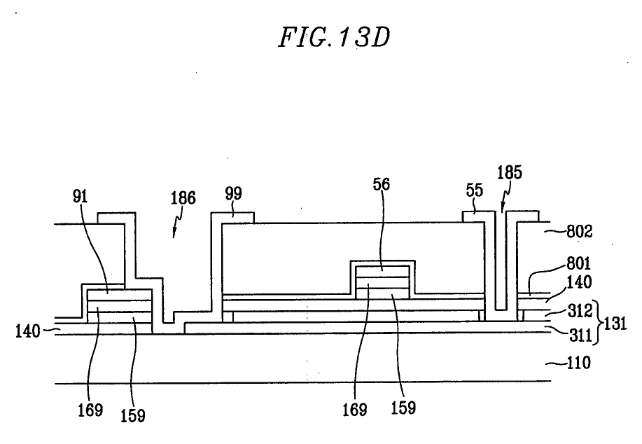

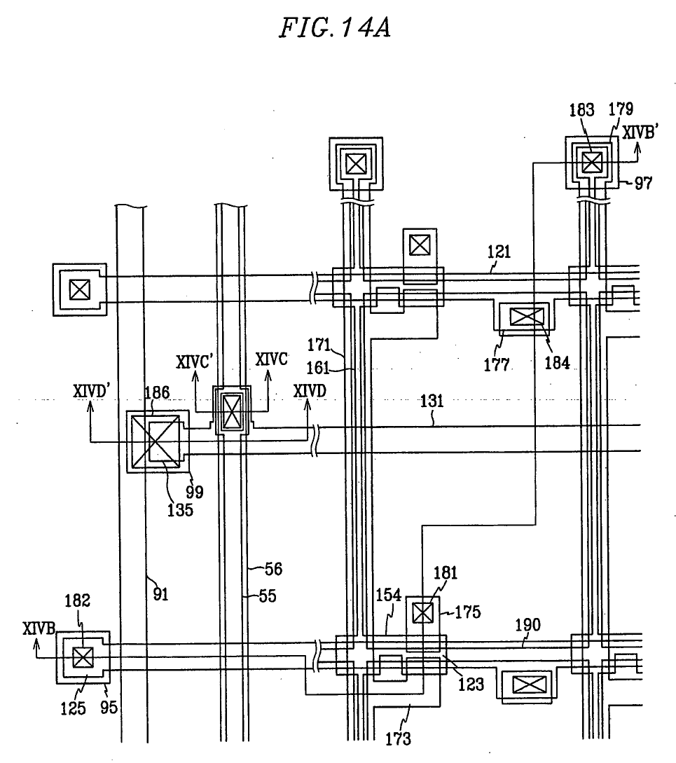

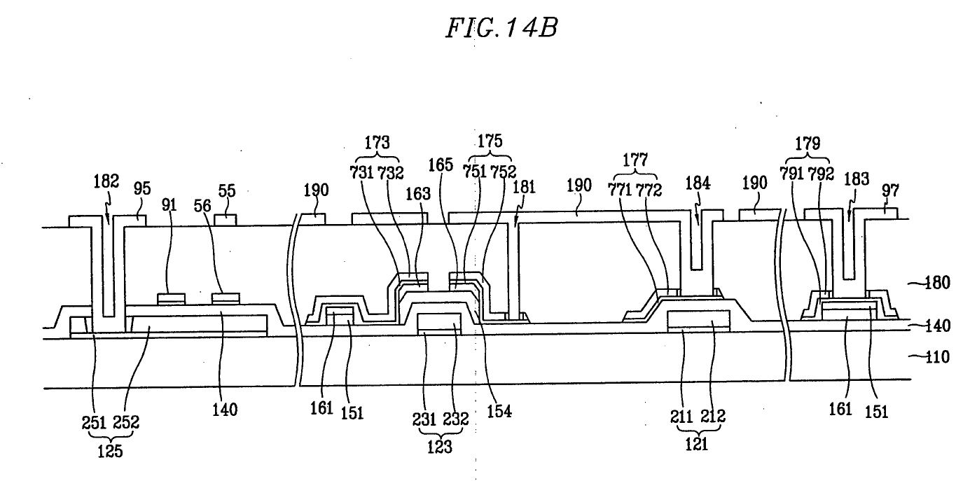

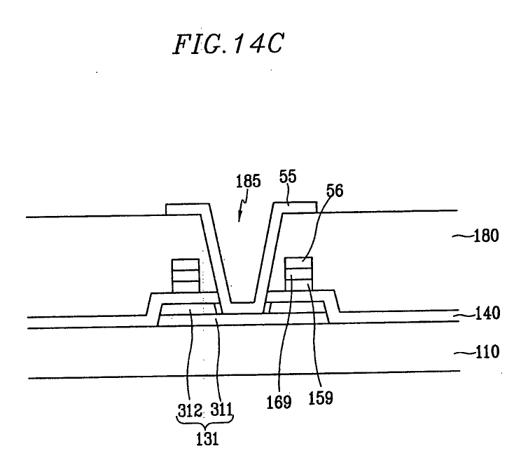

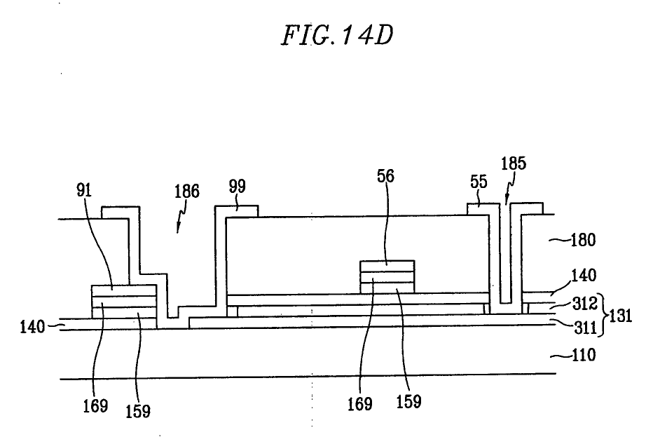

A TFT array panel for an LCD according to another embodiment of the present invention will be described in detail with reference to FIGS. 14A to 14D.

FIG. 14A is a layout view of a TFT array panel according to a fifth exemplary embodiment of the present invention. FIGS. 14B and 14D are sectional views of the TFT array panel shown in FIG. 14A respectively taken along the lines XIVB-XIVB′, XIVC-XIVC′, and XIVD-XIV.

As shown in FIGS. 14A to 14C, a plurality of gate lines 121 for transmitting gate signals and storage electrode lines 131 are formed on an insulating substrate 110.

The gate lines 121 and storage electrode lines 131 include two films having different physical characteristics, i.e., a lower film 211, 231, 251, and 311, and an upper film 212, 232, 252, and 312. The lower film 211, 231, 251, and 311 enhances adhesiveness of the gate lines 121 to the insulating substrate 110.

Each gate line 121 extends substantially in a transverse direction and it includes a plurality of portions forming a plurality of gate electrodes 123 and a plurality of projections 127 protruding downward. The gate line 121 has an end portion 125 having a large area for connection with another layer or an external driving circuit mounted on the substrate 110 or on another device such as a flexible printed circuit film (not shown) that may be attached to the substrate 110.

Each storage electrode line 131 extends substantially in a transverse direction, but it may have curved portions. The storage electrode line 131 has an end portion 135 having a large area for connecting with other storage electrode lines 131. A storage line connecting bar 91 which will be described later connects the storage electrode lines 131.

The gate lines 121 and storage electrode lines 131 are made of low resistivity metals including Al-containing metals such as Al and an Al alloy, and Ag-containing metals such as Ag and an Ag alloy; and materials such as Cr, Mo, a Mo alloy, Ta, and Ti, which have good physical, chemical, and electrical contact characteristics. In particular, the lower film 211, 231, and 251 is preferably made of a material such as Cr, Mo, a Mo alloy, Ta, and Ti, which have good physical, chemical, and electrical contact characteristics, and the upper film 212, 232, and 252 is preferably made of low resistivity metals including an Al-containing metal such as Al and Al alloy, and an Ag-containing metal such as Ag and an Ag alloy. The gate lines 121 and storage electrode line 131 may be made of other various conductors.

A gate insulating layer 140 preferably made of silicon nitride (SiNx) is formed on the gate lines 121 and storage electrode lines 131.

A plurality of semiconductor stripes 151, preferably made of a-Si, are formed on the gate insulating layer 140. Each semiconductor stripe 151 extends substantially in the longitudinal direction and has a plurality of projections 154 branched out toward the gate electrodes 124. The width of each semiconductor stripe 151 becomes large near the gate lines 121 such that the semiconductor stripe 151 covers large areas of the gate lines 121.

A plurality of ohmic contact stripes 161 and islands 165 preferably made of silicide or n+ hydrogenated a-Si heavily doped with n type impurities are formed on the semiconductor stripes 151. Each ohmic contact stripe 161 has a plurality of projections 163, and the projections 163 and the ohmic contact islands 165 are located in pairs on the projections 154 of the semiconductor stripes 151.

The data lines 171 for transmitting data voltages extend substantially in the longitudinal direction and intersect the gate lines 121. Each data line 171 includes an end portion 179 for contact with another layer or an external device, and the end portion 179 may have an increased area for enhancing the contact.

A plurality of branches of each data line 171, which project toward the drain electrodes 175, form a plurality of source electrodes 173. Each pair of the source electrodes 173 and the drain electrodes 175 are separated from each other and are opposite each other with respect to a gate electrode 123.

The storage capacitor conductors 177 overlap the projections 127 of the gate lines 121.

The data lines 171 and drain electrode 175 include two films having different physical characteristics, i.e., a lower film 711, 731, 751, and 791, and an upper film 712, 732, 752, and 792. The lower film 711, 731, 751, and 791 enhances adhesiveness and/or contact characteristic of the data lines 171 to the ohmic contacts 161 and 163.

A storage line connecting bar 91 is formed on the gate insulating layer 140 and extends substantially in the longitudinal direction.

A repair bar 56 is formed on the gate insulating layer 140 and extends substantially in the longitudinal direction.

The repair bar 56 intersects the storage electrode lines 131 and has a plurality of holes 189 to expose the intersecting portions of the storage electrode lines 131

A passivation layer 180 is formed on the data lines 171, the drain electrodes 175, the storage capacitors conductor 177, and exposed portions of the semiconductor stripes 151, which are not covered with the data lines 171 and the drain electrodes 175. The passivation layer 180 is preferably made of a photosensitive organic material having a good flatness 740 characteristic, or a low dielectric insulating material such as a-Si:C:O and a-Si:O:F formed by plasma enhanced chemical vapor deposition (PECVD). The passivation layer 180 may have a double-layered structure including a lower inorganic film preferably made of silicon nitride or silicon oxide, and an upper organic film to prevent direct contact between the semiconductor and organic material.

The passivation layer 180 has a plurality of contact holes 181, 182, 183, 184, 185, and 186 exposing the drain electrodes 175, the end portions 125 of the gate lines 121, the end portions 179 of the data lines 171, the storage conductors 177, the storage electrode lines 131 through the holes 189 of the repair bars 56, and the end portions 135 of the storage electrode lines 131, respectively.

A plurality of pixel electrodes 190 and a plurality of contact assistants 95 and 97, which are preferably made of ITO, amorphous ITO or IZO, are formed on the passivation layer 180.

The pixel electrodes 190 are physically and electrically connected to the drain electrodes 175 through the contact holes 181 and to the storage capacitor conductors 177 through the contact holes 184 such that the pixel electrodes 190 receive the data voltages from the drain electrodes 175 and transmit the received data voltages to the storage capacitor conductors 177.

The contact assistants 95 and 97 cover the contact holes 182 and 183 to be connected to the exposed end portions 125 of the gate lines 121 and the end portions 179 of the data lines 171 through the contact holes 182 and 183.

The pixel electrodes 190 overlap the data lines 171 and gate lines 121 in part to enhance the aperture ratio. However, the pixel electrodes 190 may also not overlap the data lines 171 and gate lines 121. Overlapping of the pixel electrodes 190 and the data lines 171 is allowed since the passivation layer 180 is made of a low dielectric insulating material to reduce cross talk between them.

A redundant connecting line 55 is formed on the passivation layer 180 and is connected to the storage electrode lines 131 through the contact holes 185. The redundant connecting line 55 is disposed to overlap the repair bar 56.

A plurality of storage contact assistants 99 connecting the end portion 135 of the storage electrode lines 131 and the storage line connecting bar 91 are formed on the passivation layer 180.

The storage line connecting bar 91 is disposed on the peripheral area on which the end portions 135 of the storage electrode lines 131 are disposed.

The storage line connecting bar 91 is formed on the same layer as the data lines 171 and runs parallel with the data lines 171.

In the fifth exemplary embodiment, the gate lines 121 and storage electrode lines 131 are formed of the lower film 211, 231, 251, and 311 of Cr and upper film 212, 232, 252, and 312 of Al. When Al contacts ITO, a contact defect is induced by an electrolysis effect. Therefore, the upper film 212 and 312 of Al is removed under the contact hole on which the contact assistants of ITO are disposed to prevent contact of Al with ITO (indium tin oxide).

The upper film 792, 752, and 772 of the end portions 179 of data lines 171, the drain electrodes 175, and the storage capacitor conductors 177 may also removed under the contact holes oh which the contact assistants of ITO are disposed to prevent contact of Al with ITO.

When the upper film 212 and 312 is etched to be removed under the contact holes, portions of the upper film 212 and 312 around contact holes are etched to become undercuts. These undercuts make the storage contact assistants 99 easily disconnected by static electricity or an overflow of current. Disconnection of storage contact assistant 99 induces display defects such as the transverse stain.

To prevent such display defects, the redundant connecting line 55 connecting the storage electrode lines 131 is formed on the peripheral area of an LCD.

Therefore, when a storage electrode line 131 is disconnected from the storage line connecting bar 91 due to the undercut, the storage electrode line 131 is still connected to the redundant connecting line 55 to be connected to the other storage electrode lines 131. Accordingly, display defects such as the transverse stain are prevented.

Since the redundant connecting line 55 is formed on the peripheral area outside of the display area, the redundant connecting line 55 can do a good back-up job for the storage line connecting bar 91 without diminishing the aperture ratio.

However, the contact portion of the redundant connecting line 55 and the storage electrode line 131 may also have damage from static electricity or an overflow of current, as may the contact portion of the storage line connecting bar 91 and the storage electrode line 131. In such a case, the transverse stain is shown.

As a preparation for such a case, the repair bar 56 is formed between the storage line connecting bar 91 and the redundant connecting line 55. The overlapping structure of the repair bar 56 and the redundant connecting line 55 is helpful to reduce occupying area of the repair bar 56 and the redundant connecting line 55. This structure is useful for an LCD having a narrow peripheral area. The repair bar 56 is formed of the same material and is on the same layer as the data lines 171.

The repair bar 56 may be electrically connected to the storage electrode lines 131 through laser shorting when the contact portions of the redundant connecting line 55 and the storage electrode line and of the storage line connecting bar 91 and the storage electrode line 131 have concurrent damage.

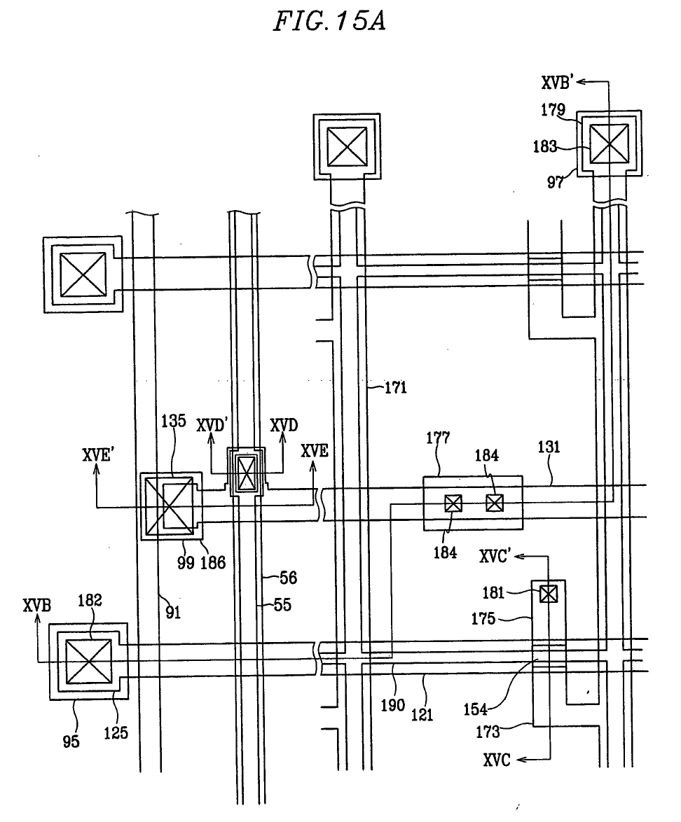

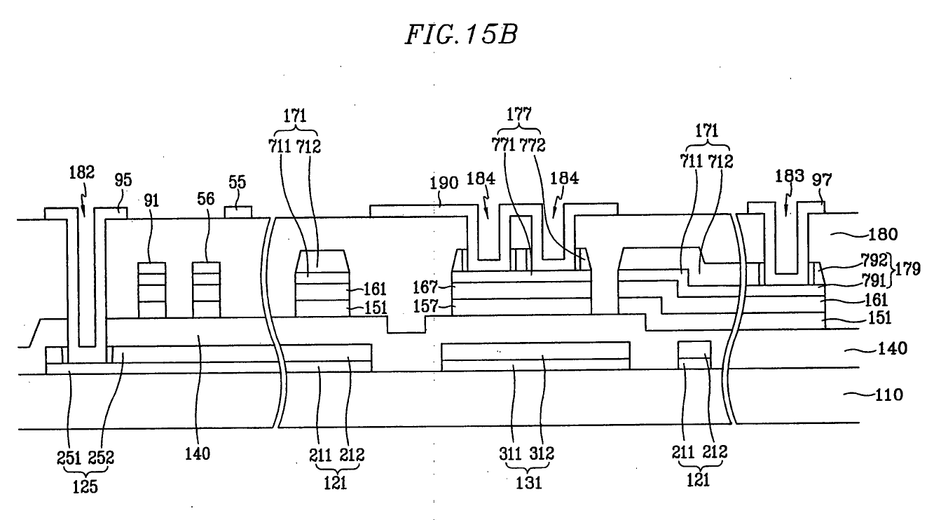

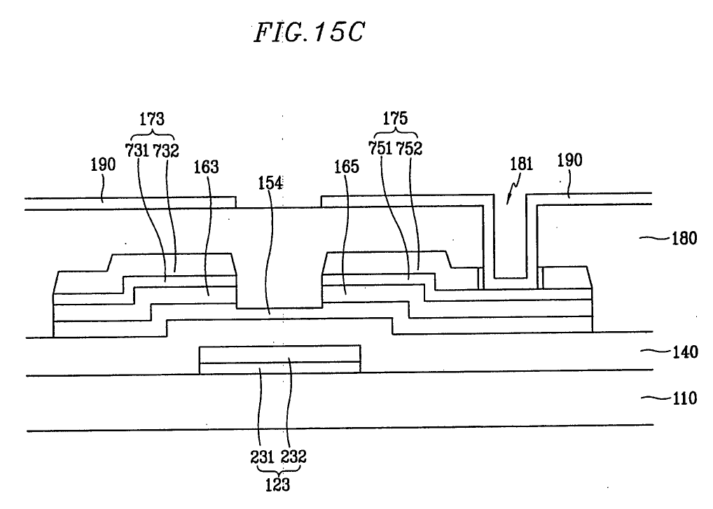

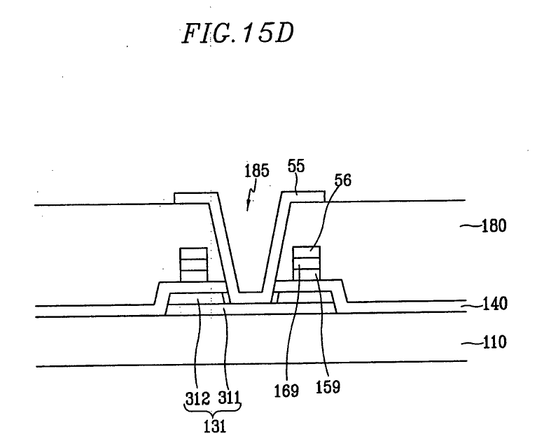

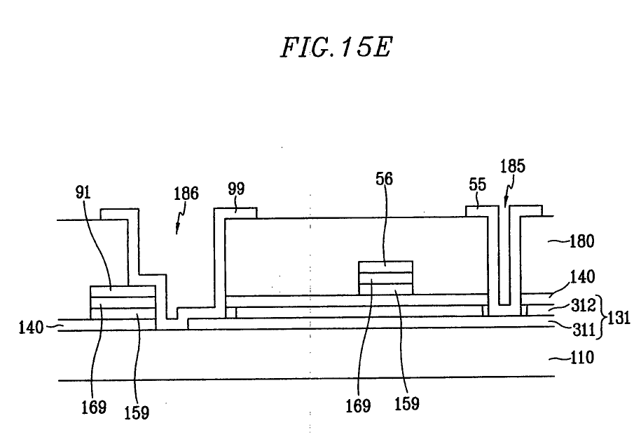

A TFT array panel for an LCD according to another embodiment of the present invention will be described in detail with reference to FIGS. 15A to 15D.

FIG. 15A is a layout view of a TFT array panel according to a sixth exemplary embodiment of the present invention. FIGS. 15B and 15E are sectional views of the TFT array panel shown in FIG. 14A respectively taken along the lines XVB-XVB′, XVC-XVC′, XVD-XVD′, and XVE-XVE′.

As shown in FIGS. 15A to 15E, a plurality of gate lines 121 for transmitting gate signals are formed on an insulating substrate 110.

The gate lines 121 include two films having different physical characteristics, i.e., a lower film 211, 231, 251, and 311 and an upper film 212, 232, 252, and 312. The lower film 211, 231, 251, and 311 enhances adhesiveness of the gate lines 121 to the insulating substrate 110.

Each gate line 121 extends substantially in a transverse direction, and includes a plurality of portions forming a plurality of gate electrodes 123. The gate line 121 has an end portion 125 having a large area for connection with another layer or an external driving circuit mounted on the substrate 110, or on another device such as a flexible printed circuit film (not shown) that may be attached to the substrate 110.

Each storage electrode line 131 extends substantially in a transverse direction, but it may have curved portions. The storage electrode line 131 has an end portion 135 having a large area for connecting with other storage electrode lines 131. A storage line connecting bar 91 which will be described later connects the storage electrode lines 131.

The gate lines 121 and storage electrode lines 131 are made of low resistivity metals including an Al-containing metal such as Al and an Al alloy, and an Ag-containing metal such as Ag and an Ag alloy; and materials such as Cr, Mo, a Mo alloy, Ta, and Ti, which have good physical, chemical, and electrical contact characteristics. In particular, the lower film 211, 231, 251, and 311 is preferably made of a material such as Cr, Mo, a Mo alloy, Ta, and Ti, which have good physical, chemical, and electrical contact characteristics, and the upper film 212, 232, 252, and 312 is preferably made of low a resistivity metal including an Al-containing metal such as Al and an Al alloy, and an Ag-containing metal such as Ag and an Ag alloy. The gate lines 121 and storage electrode line 131 may be made of other various conductors.

A gate insulating layer 140, preferably made of silicon nitride (SiNx), is formed on the gate lines 121 and storage electrode lines 131.

A plurality of semiconductor stripes 151 and islands 157, preferably made of a-Si, are formed on the gate insulating layer 140. Each semiconductor stripe 151 extends substantially in the longitudinal direction and has a plurality of projections 154 branched out toward the gate electrodes 124. The semiconductor islands 157 are disposed on the storage electrode lines 131.

A plurality of ohmic contact stripes 161 and islands 165 and 167, preferably made of silicide or n+ hydrogenated a-Si heavily doped with n type impurities are formed on the semiconductor stripes 151. Each ohmic contact stripe 161 has a plurality of projections 163, and the projections 163 and the ohmic contact islands 165 are located in pairs on the projections 154 of the semiconductor stripes 151. The other contact islands 167 are disposed on the semiconductor island 157.

A plurality of data lines 171, a plurality of drain electrodes 175, and a plurality of storage capacitor conductors 177 are formed on the ohmic contacts 161, 165, and 167.

The data lines 171 for transmitting data voltages extend substantially in the longitudinal direction and intersect the gate lines 121. Each data line 171 includes an end portion 179 for contact with another layer or an external device, and the end portion 179 may have an increased area for enhancing the contact.

The storage capacitor conductors 177 may be omitted.

The semiconductor stripes 151 have almost the same planar shapes as the data lines 171 and the drain electrodes 175, as well as the underlying ohmic contacts 161 and 165. However, the projections 154 of the semiconductor stripes 151 include some exposed portions, which are not covered with the data lines 171 and the drain electrodes 175, such as portions located between the source electrodes 173 and the drain electrodes 175, which form TFT channels.

A storage line connecting bar 91 is formed on the gate insulating layer 140, and extends substantially in the longitudinal direction.

A semiconductor bar 159 and ohmic contact bar 169 are formed under the storage line connecting bar 91, to have substantially the same planar pattern as the storage line connecting bar 91.

A repair bar 56 is formed on the gate insulating layer 140, and extends substantially in the longitudinal direction.

The repair bar 56 intersects the storage electrode lines 131, and has a plurality of holes 189 to expose the intersecting portions of the storage electrode lines 131

A passivation layer 180 is formed on the data lines 171, the drain electrodes 175, the storage capacitors conductor 177, and exposed portions of the semiconductor stripes 151 which are not covered with the data lines 171 or the drain electrodes 175.

The passivation layer 180 has a plurality of contact holes 181, 182, 183, 184, 185, and 186 exposing the drain electrodes 175, the end portions 125 of the gate lines 121, the end portions 179 of the data lines 171, the storage conductors 177, the storage electrode lines 131 through the holes 189 of the repair bars 56, and the end portions 135 of the storage electrode lines 131, respectively.

A plurality of pixel electrodes 190 and a plurality of contact assistants 95 and 97, which are preferably made of ITO, amorphous ITO or IZO, are formed on the passivation layer 180.

The pixel electrodes 190 are physically and electrically connected to the drain electrodes 175 through the contact holes 181 and to the storage capacitor conductors 177 through the contact holes 184 such that the pixel electrodes 190 receive the data voltages from the drain electrodes 175 and transmit the received data voltages to the storage capacitor conductors 177.

The contact assistants 95 and 97 cover the contact holes 182 and 183 to be connected to the exposed end portions 125 of the gate lines 121 and the end portions 179 of the data lines 171 through the contact holes 182 and 183.

The pixel electrodes 190 overlap the data lines 171 and gate lines 121 in part to enhance the aperture ratio. However, the pixel electrodes 190 may also not overlap the data lines 171 and gate lines 121. Overlapping of the pixel electrodes 190 and the data lines 171 is allowed since the passivation layer 180 is made of a low dielectric insulating material to reduce cross talk between them.

A redundant connecting line 55 is formed on the passivation layer 180 and is connected to the storage electrode lines 131 through the contact holes 185. The redundant connecting line 55 is disposed to overlap the repair bar 56.

A plurality of storage contact assistants 99 connecting the end portion 135 of the storage electrode lines 131 and the storage line connecting bar 91 are formed on the passivation layer 180.

The storage line connecting bar 91 is disposed on the peripheral area on which the end portions 135 of the storage electrode lines 131 are disposed.

The storage line connecting bar 91 is formed on the same layer as the data lines 171, and runs parallel with the data lines 171.

In the third exemplary embodiment, the gate lines 121 and storage electrode lines 131 are formed of the lower film 211, 231, 251, and 311 of Cr and upper film 212, 232, 252, and 312 of Al. When Al contacts ITO, a contact defect is induced by an electrolysis effect. Therefore, the upper film 212, 232, 252, and 312 of Al is removed under the contact hole on which the contact assistants of ITO are disposed to prevent contact of Al and ITO (indium tin oxide).

When the upper film 212, 232, 252, and 312 is etched to be removed under the contact holes, portions of the upper film 212, 232, 252, and 312 around contact holes are etched to become undercuts. These undercuts make the storage contact assistants 99 easily disconnected by static electricity or an overflow of current. Disconnection of the storage contact assistant 99 induces display defects such as the transverse stain.

To prevent such display defects, the redundant connecting line 55 connecting the storage electrode lines 131 is formed on the peripheral area of an LCD.

Therefore, when a storage electrode line 131 is disconnected from the storage line connecting bar 91 due to the undercut, the storage electrode line 131 is still connected to the redundant connecting line 55 to be connected to the other storage electrode lines 131. Accordingly, display defects such as the transverse stain is prevented.

Since the redundant connecting line 55 is formed on the peripheral area outside of the display area, the redundant connecting line 55 can do a good back-up job for the storage line connecting bar 91 without diminishing the aperture ratio.

However, the contact portion of the redundant connecting line 55 and the storage electrode line 131 may also have damage from static electricity or an overflow of current as well as the contact portion of the storage line connecting bar 91 and the storage electrode line 131. In such a case, the transverse stain is shown.

As a preparation for such a case, the repair bar 56 is formed between the storage line connecting bar 91 and the redundant connecting line 55. The overlapping structure of the repair bar 56 and the redundant connecting line 55 is helpful to reduce the occupying area of the repair bar 56 and the redundant connecting line 55. This structure is useful for an LCD having a narrow peripheral area. The repair bar 56 is formed of the same material and is on the same layer as the data lines 171.

The repair bar 56 may be electrically connected to the storage electrode lines 131 through laser shorting when the contact portions of the redundant connecting line 55 and the storage electrode line and of the storage line connecting bar 91 and the storage electrode line 131 have concurrent damage.

In the meantime, color filters may be formed on the TFT array substrate of the fifth and sixth exemplary embodiment of the present invention.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A thin film transistor array panel comprising:
an insulating substrate;
a plurality of gate lines formed on the insulating substrate and including a plurality of gate electrodes and end portions;
a plurality of storage electrode lines formed on the insulating substrate;
a gate insulating layer formed on the gate lines and storage electrode lines;
a semiconductor layer formed on the gate insulating layer;
a ohmic contact layer formed on the semiconductor layer;
a plurality of data lines formed on the gate insulating layer, intersecting the gate lines to define display area, and having source electrodes and end portions;
a plurality of drain electrodes facing the source electrodes;
a passivation layer formed on the data lines and drain electrodes and having contact holes;
a plurality of pixel electrodes formed on the passivation layer and connected to the drain electrodes through the contact holes;
a storage line connecting bar connecting the storage electrode lines; and
a redundant connecting line connecting the storage electrode lines.

2. The thin film transistor array panel of claim 1, wherein the storage line connecting bar is formed on the gate insulating layer, and the passivation layer and gate insulating layer have contact holes exposing the storage line connecting bar and the storage electrode lines, and
further comprises storage contact assistants connecting the storage line connecting bar and the storage electrode lines through the contact holes.

3. The thin film transistor array panel of claim 1, wherein the passivation layer and gate insulating layer have contact holes exposing the storage electrode lines, and the redundant connecting bar is connected to the storage electrode lines through the contact holes.

4. The thin film transistor array panel of claim 1, further comprises a repair bar formed on the gate insulating layer, disposed between the storage line connecting bar and the redundant connecting bar, and intersecting the storage electrode lines.

5. The thin film transistor array panel of claim 4, wherein the repair bar and the redundant connecting bar overlap each other.

6. The thin film transistor array panel of claim 5, wherein the passivation layer and gate insulating layer have contact holes exposing the storage electrode lines, the repair bar has penetrating holes, and the contact holes are disposed in the penetrating holes.

7. A thin film transistor array panel comprising:
an insulating substrate;
a plurality of gate lines formed on the insulating substrate and including a plurality of gate electrodes and end portions;
a plurality of storage electrode lines formed on the insulating substrate;
a gate insulating layer formed on the gate lines and storage electrode lines;
a semiconductor layer formed on the gate insulating layer;
a ohmic contact layer formed on the semiconductor layer;
a plurality of data lines and drain electrodes formed on the ohmic contact layer and having substantially the same planar pattern as the ohmic contact layer;
a passivation layer formed on the data lines and drain electrodes and having contact holes;
a plurality of pixel electrodes formed on the passivation layer and connected to the drain electrodes through the contact holes;
a storage line connecting bar connecting the storage electrode lines; and
a redundant connecting line connecting the storage electrode lines.

8. The thin film transistor array panel of claim 7, wherein the storage line connecting bar is formed on the gate insulating layer, and the passivation layer and gate insulating layer has contact holes exposing the storage line connecting bar and the storage electrode lines, and
further comprising storage contact assistants connecting the storage line connecting bar and the storage electrode lines.

9. The thin film transistor array panel of claim 7, wherein the passivation layer and gate insulating layer have contact holes exposing the storage electrode lines, and the redundant connecting bar is connected to the storage electrode lines through the contact holes.

10. The thin film transistor array panel of claim 7, further comprises a repair bar formed on the gate insulating layer, disposed between the storage line connecting bar and the redundant connecting bar, and intersecting the storage electrode lines.

11. The thin film transistor array panel of claim 10, wherein the repair bar and the redundant connecting bar overlap each other.

12. The thin film transistor array panel of claim 11, wherein the passivation layer and gate insulating layer have contact holes exposing the storage electrode lines, the repair bar has penetrating holes, and the contact holes are disposed in the penetrating holes

13. A thin film transistor array panel comprising:
an insulating substrate;
a plurality of gate lines formed on the insulating substrate and including a plurality of gate electrodes and end portions;
a plurality of storage electrode lines formed on the insulating substrate;
a gate insulating layer formed on the gate lines and storage electrode lines;
a semiconductor layer formed on the gate insulating layer;
a ohmic contact layer formed on the semiconductor layer;
a plurality of data lines formed on the gate insulating layer, intersecting the gate lines to define display area, and having source electrodes and end portions;
a plurality of drain electrodes facing the source electrodes;
a plurality of color filters formed on the data lines and having a first contact holes exposing the drain electrodes;
a passivation layer formed on the data lines and drain electrodes and having a second contact holes overlapping at least a portion of the first contact holes to expose the drain electrodes;
a plurality of pixel electrodes formed on the passivation layer and connected to the drain electrodes through the second contact holes;
a storage line connecting bar connecting the storage electrode lines; and
a redundant connecting line connecting the storage electrode lines.

14. The thin film transistor array panel of claim 13, wherein the storage line connecting bar is formed on the gate insulating layer, and the passivation layer and gate insulating layer have third contact holes exposing the storage line connecting bar and the storage electrode lines, and
further comprising storage contact assistants connecting the storage line connecting bar and the storage electrode lines through the third contact holes.

15. The thin film transistor array panel of claim 13, wherein the passivation layer and gate insulating layer have fourth contact holes exposing the storage electrode lines, and the redundant connecting bar is connected to the storage electrode lines through the fourth contact holes.

16. The thin film transistor array panel of claim 13, further comprising a repair bar formed on the gate insulating layer, disposed between the storage line connecting bar and the redundant connecting bar, and intersecting the storage electrode lines.

17. The thin film transistor array panel of claim 16, wherein the repair bar and the redundant connecting bar overlap each other.

18. The thin film transistor array panel of claim 17, wherein the passivation layer and gate insulating layer have fifth contact holes exposing the storage electrode lines, the repair bar has penetrating holes, and the fifth contact holes are disposed in the penetrating holes

19. A thin film transistor array panel comprising:
an insulating substrate;
a plurality of gate lines formed on the insulating substrate and including a plurality of gate electrodes and end portions;
a plurality of storage electrode lines formed on the insulating substrate;
a gate insulating layer formed on the gate lines and storage electrode lines;
a semiconductor layer formed on the gate insulating layer;
a ohmic contact layer formed on the semiconductor layer;
a plurality of data lines and drain electrodes formed on the ohmic contact layer and having substantially the same planar pattern as the ohmic contact layer;
a plurality of color filters formed on the data lines and having a first contact holes exposing the drain electrodes;
a passivation layer formed on the data lines and drain electrodes and having a second contact holes overlapping at least a portion of the first contact holes to expose the drain electrodes;
a plurality of pixel electrodes formed on the passivation layer and connected to the drain electrodes through the second contact holes;
a storage line connecting bar connecting the storage electrode lines; and
a redundant connecting line connecting the storage electrode lines.

20. The thin film transistor array panel of claim 19, wherein the storage line connecting bar is formed on the gate insulating layer, and the passivation layer and gate insulating layer have third contact holes exposing the storage line connecting bar and the storage electrode lines, and
further comprising storage contact assistants connecting the storage line connecting bar and the storage electrode lines through the third contact holes.

21. The thin film transistor array panel of claim 19, wherein the passivation layer and gate insulating layer have fourth contact holes exposing the storage electrode lines, and the redundant connecting bar is connected to the storage electrode lines through the fourth contact holes.

22. The thin film transistor array panel of claim 19, further comprising a repair bar formed on the gate insulating layer, disposed between the storage line connecting bar and the redundant connecting bar, and intersecting the storage electrode lines.

23. The thin film transistor array panel of claim 22, wherein the repair bar and the redundant connecting bar overlap each other.

24. The thin film transistor array panel of claim 23, wherein the passivation layer and gate insulating layer have fifth contact holes exposing the storage electrode lines, the repair bar has penetrating holes, and the fifth contact holes are disposed in the penetrating holes.
